(19) United States
(12) Patent Application Publication
(10) Pub. No.: US 2016/0337731 A1
(43) Pub. Date: Nov. 17, 2016

(54) System and Method for Photonic Switching

(71) Applicant: Huawei Technologies Co., Ltd., Shenzhen (CN)

(72) Inventor: Alan Frank Graves, Kanata (CA)

(21) Appl. No.: 14/710,815

(22) Filed: May 13, 2015

(51) Int. Cl. H04Q 11/00; G02B 6/43; H01S 5/00; G02B 6/122; G02B 6/35

(52) U.S. Cl. CPC H04Q 11/0062; G02B 6/1225; G02B 6/3596; H01S 5/0071; G02B 6/43; G02B 6/3588; H04Q 11/0005; G02B 2006/12145

(57) ABSTRACT

A photonic switching structure includes a first macromodule, where the first macromodule includes an array of switch matrix photonic integrated circuit (PIC) nodes having a first row, a second row, a first column, and a second column and a first optical splitter optically coupled to PIC nodes in the first row. The first macromodule also includes a second optical splitter optically coupled to PIC nodes in the second row and a first output selector optically coupled to PIC nodes in the first column. Additionally, the first macromodule includes a second output selector optically coupled to PIC nodes in the second column and a first collision detector coupled to PIC nodes in the first column. Also, the first macromodule includes a second collision detector coupled to PIC nodes in the second column.

### TECHNICAL FIELD

The present invention relates to a system and method for packet switching, and, in particular, to a system and method for photonic switching.

### BACKGROUND

Data centers route massive quantities of data. Currently, data centers may have a throughput of 5-10 terabytes per second, which is expected to substantially increase in the future. Data centers contain huge numbers of racks of servers, racks of storage devices, and other racks often with top-of-rack (TOR) switches, all of which are interconnected via massive centralized packet switching resources. In data centers, electrical packet switches are used to route all data packets, irrespective of packet properties, in these data centers. However, electrical packet switches have limited capacities.

It is desirable to increase this packet switching capacity, for example by using a very fast photonic switch, for example to switch short packet containers in a large data center, in a small data center, or in large high speed computing clusters.

### SUMMARY

An embodiment photonic switching structure includes a first macromodule, where the first macromodule includes an array of switch matrix photonic integrated circuit (PIC) nodes having a first row, a second row, a first column, and a second column and a first optical splitter optically coupled to PIC nodes in the first row. The first macromodule also includes a second optical splitter optically coupled to PIC nodes in the second row and a first output selector optically coupled to PIC nodes in the first column. Additionally, the first macromodule includes a second output selector optically coupled to PIC nodes in the second column and a first collision detector coupled to PIC nodes in the first column. Also, the first macromodule includes a second collision detector coupled to PIC nodes in the second column.

An embodiment method includes serially loading signaling input port requests into a plurality of input shift registers and loading addresses from the plurality of input shift registers into a plurality of output shift registers. The method also includes reading out comparison bits from the plurality of output shift registers and determining input port contention in accordance with the comparison bits.

An embodiment method includes receiving a plurality of output port requests for a frame and detecting collisions between the plurality of output port requests. The method also includes resolving detected collisions by selecting a first output port request for a first requested output port, and rejecting remaining output port requests and selecting a first output of a photonic switch module in accordance with the first output port request to connect the first output of the photonic switch module to the first requested output port. Additionally, the method includes transmitting negative acknowledgments (NACKs) corresponding to the rejected output port requests.

An embodiment method includes transmitting, by a peripheral to a photonic switch, a connection request corresponding to a container to be assembled and transmitting, by the peripheral to a photonic switch, the container. The method also includes storing a copy of the container in a sent container store and determining whether a negative acknowledgment (NACK) corresponding to the connection request has been received. Additionally, the method includes re-transmitting, by the peripheral to the photonic switch, the copy of the container in response to receiving the NACK.

The foregoing has outlined rather broadly the features of an embodiment of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates an embodiment photonic switching structure;

FIG. 2 illustrates an embodiment hybrid dilated Benes photonic integrated circuit (PIC);

FIG. 3 illustrates an embodiment controller for a hybrid dilated Benes PIC;

FIG. 4 illustrates an embodiment enhanced dilated Benes PIC;

FIG. 5 illustrates an embodiment controller for an enhanced dilated Benes PIC;

FIGS. 6A-B illustrate an embodiment photonic switching configuration;

FIG. 7 illustrates an embodiment photonic switching fabric;

FIG. 8 illustrates an embodiment macromodule based photonic switching fabric;

FIGS. 9A-D illustrate another embodiment macromodule based photonic switching fabric;

FIG. 10 illustrates another embodiment optical macromodule;

FIGS. 11A-B illustrate an additional embodiment optical macromodule;

FIG. 12 illustrates another embodiment macromodule based photonic switching fabric;

FIG. 13 illustrates an additional embodiment macromodule based photonic switching fabric;

FIGS. 14A-B illustrate another embodiment macromodule based photonic switching fabric;

FIGS. 15A-C illustrates an embodiment input contention resolution system;

FIG. 16 illustrates an embodiment contention resolution system;

FIG. 17 illustrates an embodiment rectangular orthogonal multiplexer;

FIG. 18 illustrates another embodiment rectangular orthogonal multiplexer;

FIG. 19 illustrates an embodiment output contention resolution system;

FIG. 20 illustrates a flowchart of an embodiment method of contention resolution;

FIG. 21 illustrates a flowchart of an embodiment method of photonic switching with contention resolution;

FIG. 22 illustrates a flowchart of an embodiment method of input contention resolution;

FIG. 23 illustrates a flowchart of an embodiment method of PIC row output contention resolution;

FIG. 24 illustrates a flowchart of an embodiment method of macromodule output contention resolution; and

FIG. 25 illustrates a flowchart of an embodiment method of contention resolution performed by a peripheral.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

It should be understood at the outset that although an illustrative implementation of one or more embodiments are provided below, the disclosed systems and/or methods may be implemented using any number of techniques, whether currently known or in later developed. The disclosure should in no way be limited to the illustrative implementations, drawings, and techniques illustrated below, including the designs and implementations illustrated and described herein, but may be modified within the scope of the appended claims along with their full scope of equivalents.

Electronic switches may have a high port count with a limited overall capacity, because the bandwidth capacity of each port is limited. The overall total capacity is the number of ports multiplied by the capacity per port. This overall total capacity may increase, even with fewer ports, when the capacity per port is very high, for example 100 Gb/s or 400 Gb/s.

An embodiment photonic switch has a moderate port count (hundreds to thousands of ports) and is agile and fast, with a low delay for set up using direct control, without interactive connection mapping, to allow fast set up times and short switched payload building block times, for example 30-40 ns or less. A directly addressable matrixed topology is used. Fast distributed output port contention resolution is used, and the switch resolves contention within sub-groups of input ports on the input side of the switch and resolves contention between sub-groups of output ports on the output side of the switch. Also, the switch uses a contention management approach where peripherals transmit containers before receiving acknowledgments (ACK) from the switch that the container is able to be switched, and the source stores transmitted containers for re-transmission after receiving a negative acknowledgment (NACK) or deletion after receiving an ACK. This facilitates switching promptly after requesting a connection. An embodiment has a low contention resolution and switch set up lead time.

In one embodiment, a photonic switch has a port count of 256×256, 512×512, 1024×1024, or more ports, such as 2048×2048. It is based on silicon photonic integrated circuits (PICs) for the physical set up of the matrix cells, which may have port counts of, for example, 16×16, 32×32 or 64×64, and which switch containerized optical data streams at a high bandwidth, for example 100 Gb/s or 400 Gb/s, and switch containers with 1-3 ns inter-container gaps (ICGs). A fast synchronous switching architecture with frame times of, for example, 40 ns at 100 Gb/s may be used, which provides approximately a 97.5% switching bandwidth efficiency (available payload container duration/overall frame time including ICG) with a 1 ns ICG. Direct fabric level switch addressing allows the steps of the switching process to be driven directly or almost directly from a port-to-port connection request message. Within the fabric, the PICs may also use direct addressing for higher speeds with a higher PIC cell count, or local PIC-specific indirect addressing for a lower photonic cell count. In one example, a matrixed switching topology is used. A multi-chip optical macromodule approach can be used for a low loss, polarization agnostic, and low skew photonic switching module. Polarization agnostic switching may be achieved in the macromodule with hybrid or monolithic integration. A distributed high speed output port contention detection and resolution system may be used to avoid output port collisions and provide feedback to the source peripherals for dropped containers to trigger re-transmission of the containers from the peripheral.

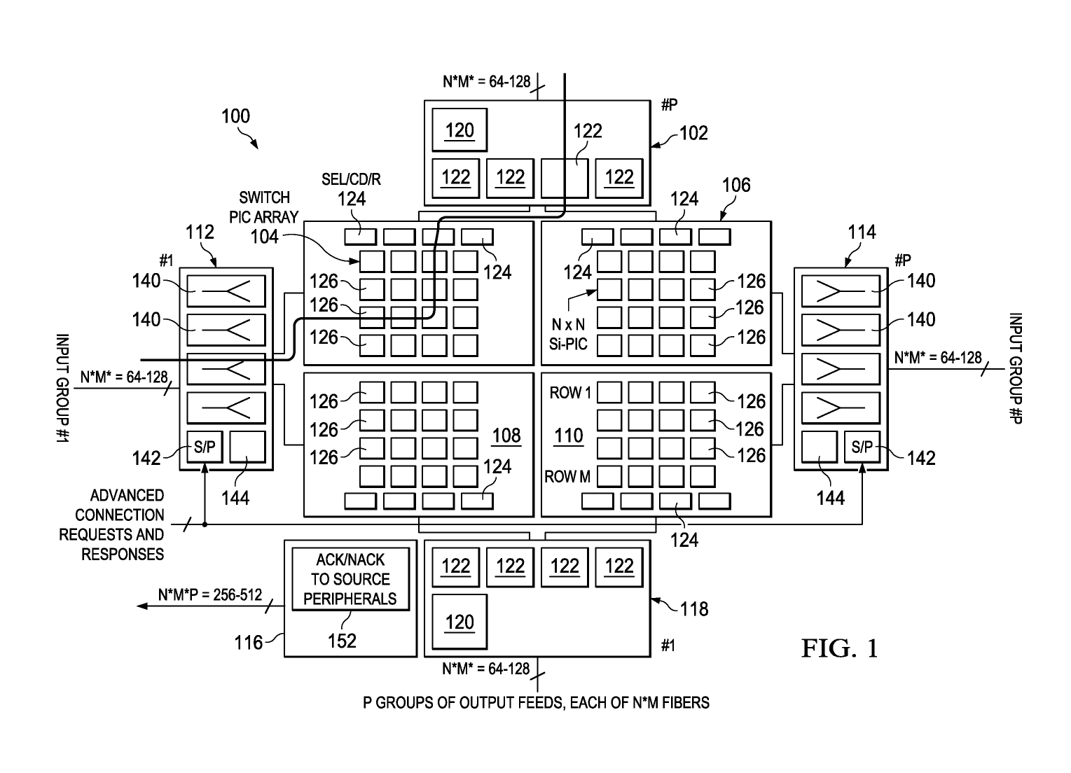

FIG. 1 illustrates an ultrafast photonic switching fabric 100. The speed (fast or ultra-fast) is determined by several factors, including the actual switching speed of the physical photonic cells once they are commanded to change state and the speed at which new connection maps are generated and supplied to the switch in a synchronous space switching application. The former is determined by the time it takes the photonic crosspoints to change state which, for electro-optic Mach Zehnder based 2×2 or 1×2 crosspoints, is less than about 3 ns. The speed of supplying the connection maps (and hence the frame time) depends on the switching efficiency, and the complexity of generating large contention free connection maps across the ports, especially when the connection paths of the different inputs to the different outputs are interactive throughout the switch. For a large dilated Clos switch, the lower limit on the frame period is from about 100 ns to about 150 ns, which may result in under-filled containers at 100 Gb/s when those containers are carrying just a few short packets between a particular source and destination. This long frame time is related to the complexity of the connection processing even when using a series/parallel pipelined processing array.

Shorter frame times may be achieved by using the container destination addressing directly in a switch structure which has no path-to-path interactions besides output port blocking, which arises because only one input can connect to any one output at any given time. Thus, it is desirable that each part of the switch topology is directly controlled by bits within the incoming destination binary address (and optionally the source address) without a complex address mapping computation. Such a switch may be controlled with short frame times, based on the data-link speed of the link providing the addresses and by the bandwidth efficiency. For a bandwidth efficiency of 90% and a physical cell switching time of about 1-3 ns, the frame time is 10 times the ICG, or about 10-30 ns. An example ultrafast switch switches at frame rates substantially faster than 100 ns, such as about 10-30 ns. In some examples, a fast switch switches in the 100 ns to 1000 ns range.

Photonic switching fabric 100, shown in FIG. 1, has a photonic traffic switching plane, which switches short duration fixed length containers within input very high capacity optical streams (for example 40 Gb/s, 100 Gb/s, or higher), and a connection request signaling reception and processing system, which contains a two stage contention detection and resolution system, with direct addressing of each section of the switching paths and a lack of internal interaction between the routing of each switch path.

Photonic traffic input data streams are applied to input groups 1 to P, where P=2 in FIG. 1. Each input group has N inputs from different sources, such as different top-of-rack switches (TORs), with streams destined for different combinations of destinations. There are instances within each group of requests being made for the same destination, causing output contention within the group, and instances of different groups having simultaneous requests for the same output port causing output contention.

These inputs are optically power-split by arrays of splitters 140 on input blocks 112 and 114, so copies of the inputs are fed to P macromodules 104, 106, 108, and 110, which are hybridized large area precision optical substrates with integrated monolithic optical passive components, optical tracking, and arrays of hybridized photonic and electronic components, including arrays of switch PIC matrices 126 and their corresponding controllers. The macromodules perform optical switching. The macromodules also include selector/output row collision detectors on combiners 124. On macromodules 104, the optical inputs are further optically power-split and fed in parallel into the inputs of a row of M switch matrix PICs, each of which has N inputs and N outputs, which receives optical feeds from N input optical data streams. The optical signal to be switched is then only switched by one of the M PICs.

The M×M PICs of the array of PICs on the macromodule also form columns, which may be associated with sub-groups of outputs. The N×N PICs in each row which interfaces into each output column have outputs delivered to an on-macromodule combiner 124, which selects one of the columns to connect to the macromodule optical output for each port of that sub-group, so a PIC will not over-write the output data of another PIC. The output of the on-macromodule output combiner 124 is combined with the outputs of the other P−1 macromodules feeding that output group by combiner 122, which is are port-by-port optical selector switches located on macromodule 118 and macromodule 102. By splitting the inputs over a P×P array of macromodules, each of which carries an M×M array of N×N PIC matrices, an (N*M*P)×(N*M*P) ultra-fast directly addressable photonic switch fabric switching may be formed.

The signaling request inputs from the sub-groups of sources, for example TORs, are converted from serial to parallel by serial-to-parallel (S/P) converter 142.

During this conversion process, a collision detection module 144 detects the presence within each sub-group of contending requests for the same output port in the same frame period, which would cause an output collision. The contention resolution algorithm associated with the contention detection block causes all but one of the contending requests to be blocked, where the selected request is gated out of the address bus. Blocked connection requests are notified to the collision detection/resolution messaging block 152 in module 116.

The address sub-groups, each of which is now a contention resolved address bus carrying the N addresses of one row of PICs on the macromodule, are fed to the macromodule and the PICs on that macromodule. Part of the destination address is used to enable one of the P macromodules, part of the destination address is used to enable one of the M PICs in the associated row on that macromodule, and part of the destination address is used to address the connection in the PICs. For example, when P=2, M=4, and N=32, one bit is used to address the macromodule to be enabled, 2 bits are used to address the PIC to be enabled, and 5 bits are used to select the PIC output port to connect to a given input port, where there are N=32 instantiations of this address word per frame per PIC-row. The PIC address information is passed to the combiner 124, an on-macromodule combiner, which uses this information to select the PIC row to connect to the associated column outputs. When two PIC rows request an output on the same output port in the same frame, contention detection and resolution module 120 is associated with combiner 124. Contention detection and resolution module 120 operates similarly to collision detection module 144.

Thus, the selected switched photonic output is passed via combiner 124 to combiner 122, while connection requests are sent to the collision detection/resolution messaging block 152 in module 116. The inter-macromodule combiner uses the macromodule enable address portion of the address to detect when two or more incoming optical feeds from the macromodules within the group contain contending output port requests. All but one of the requests are rejected, and a message is passed to the collision detection/resolution messaging block 152 in module 116. At the end of the switching cycle for a frame, the collision detection/resolution messaging block 152 in module 116 signals an ACK to each source which has been successfully switched and a NACK to each source which has been blocked. The process of transmitting the switched data traffic container from the source before receiving an ACK at the source, along with storing the transmitted data container at the source for retransmission upon receiving a NACK, and deleting the stored data container upon receiving an ACK, leads to a fully contention resolved switch with retransmission of colliding containers such as packet containers.

Then, collision detection/resolution messaging block 152 transmits ACK and NACK messages to source peripherals. NACK messages are transmitted as collisions are detected and resolved, and ACK messages are transmitted when collision detection and resolution is complete.

It is desirable for an ultrafast photonic switch to have a relatively high port count, for example 256×256, 512×512, 1024×1024, or larger, for example 2048×2048 for use as a highly agile switch for handling short containers. A three stage architecture, such as a Clos switch, may be problematic in an ultrafast switch, because of a lack of agility from complex inter-stage connectivity interactions during the connection computation process. PICs with a smaller port count, such as 16×16, 32×32, or 64×64, or another port count, may be assembled in a matrixed structure. A matrixed structure is directly addressable, has independent switching paths without blocking or path interactions other than output port contention when two inputs attempt to simultaneously connect to the same output. A matrixed switch with a high matrixing gain may have a large number of individual switch nodes, because the number of nodes equals the square of the matrixing gain. The physical complexity may be reduced by assembling arrays of unpackaged PIC chips on macromodules.

Table 1 shows the matrixing gain and number of nodes for various sizes of overall switch fabrics and PIC size. The number of PICs is large for matrixing gains of more than 8-16. However, the physical complexity from using a large number of PICs may be reduced when the PICs are mounted as arrays of unpackaged dies on a macromodule substrate, where the macromodule substrate handles the interconnect lithographically.

TABLE 1

| | Si-PIC | | # of |
|---|---|---|---|
| Switch Fabric Port Count | Port Count | Matrixing Gain | Si-PICs Required |
| 64 × 64 | 16 × 16 | 4 | 16 |
| 64 × 64 | 32 × 32 | 2 | 4 |
| 128 × 128 | 16 × 16 | 8 | 64 |
| 128 × 128 | 32 × 32 | 4 | 16 |
| 128 × 128 | 64 × 64 | 2 | 4 |
| 256 × 256 | 16 × 16 | 16 | 256 |
| 256 × 256 | 32 × 32 | 8 | 64 |
| 256 × 256 | 64 × 64 | 4 | 16 |
| 512 × 512 | 16 × 16 | 32 | 1024 |
| 512 × 512 | 32 × 32 | 16 | 256 |
| 512 × 512 | 64 × 64 | 8 | 64 |
| 1024 × 1024 | 16 × 16 | 64 | 4096 |
| 1024 × 1024 | 32 × 32 | 32 | 1024 |
| 1024 × 1024 | 64 × 64 | 16 | 256 |

Table 2 shows loss (as a function of the per cell insertion loss (IL)), crosstalk, and cell count for some example expand-and-select matrix (ESM) PICs, which are directly addressable, and Table 3 shows loss, crosstalk, and cell count for some example hybrid dilated Benes (HDBE) PICs, which are indirectly addressable. The switching speed ranges from <1 ns to about 3-5 ns. The PICs may be single polarization switch chips with the entire switch chip being one large matrix, or polarization agnostic switch chips with two smaller switch matrices and polarization splitters, rotators, and combiners.

TABLE 2

| Configuration | Loss (dB) Across Matrix | Crosstalk | Cell Count |
|---|---|---|---|
| 1 × 4 | 2 * IL | N/A | 3 |
| 1 × 8 | 3 * IL | N/A | 7 |
| 4 × 8 | 5 * IL | N/A | 52 |
| 8 × 8 | 6 * IL | 35-45 | 112 |
| 8 × 16 | 7 * IL | N/A | 232 |
| 16 × 32 | 8 * IL | 32-42 | 480 |
| 16 × 32 | 9 * IL | N/A | 976 |
| 32 × 32 | 10 * IL | 29-39 | 1984 |
| 64 × 64 | 12 * IL | 26-36 | 8064 |

TABLE 3

| Configuration | Loss (dB) Across Matrix | Crosstalk | Cell Count |
|---|---|---|---|
| 1 × 4 | 2 * IL | N/A | 3 |
| 1 × 8 | 3 * IL | N/A | 7 |
| 4 × 8 | 7 * IL | N/A | 52 |
| 8 × 8 | 8 * IL | 28-31 | 80 |
| 8 × 16 | 9 * IL | N/A | 168 |
| 16 × 32 | 10 * IL | 25-28 | 192 |
| 16 × 32 | 11 * IL | N/A | 400 |
| 32 × 32 | 12 * IL | 22-25 | 448 |
| 64 × 64 | 14 * IL | 19-22 | 1024 |

In a synchronous photonic switch, connections are written every frame into an empty slate, and the previous set of containers has already been fully cleared by the switch. In a fast synchronous switch, the switched bandwidth or throughput is quantized into packets or containers. In a 2 μs burst mode switch, the containers may be about 25,000 payload bytes for 100 Gb/s. When a container has a single 50 byte ACK packet, the container is 500 times the size of a single packet. In a short container switch, for example, a switch with a 40 ns container, the 50 byte packet takes up around 10% of a container.

In direct fabric level switch addressing, the input port and output port address numbering in binary form may be used to directly operate various parts of the switching process without address modifications or a free path algorithm or search. In a matrixing switch, the address breaks down into output column addresses and port addresses for the PICs feeding these columns. The address may flow straight into the PICs, for a low processing related set up time. This allows the addresses to be changed frequently, permitting the use of short frame periods, short container durations, and many containers per port for a fine switching granularity.

Input and output port contention resolution both involve some delay while the addresses for a frame are assessed to determine whether two or more containers are attempting to use the same output port. In both cases, contention is resolved by blocking all but one of the contending requests, and triggering a NACK based re-transmission for rejected containers. At the end of the overall process for each frame, the remaining successful connections result in an ACK being returned to the source of each connection.

While the address mapping of the photonic switching fabric with a set of input-output instructions to the PIC may be simple and direct, the addressing is applied to the cells inside the PIC. This may be direct, for example with an ESM topology. On the other hand, the cell addressing may be indirect, for example in a HDBE topology.

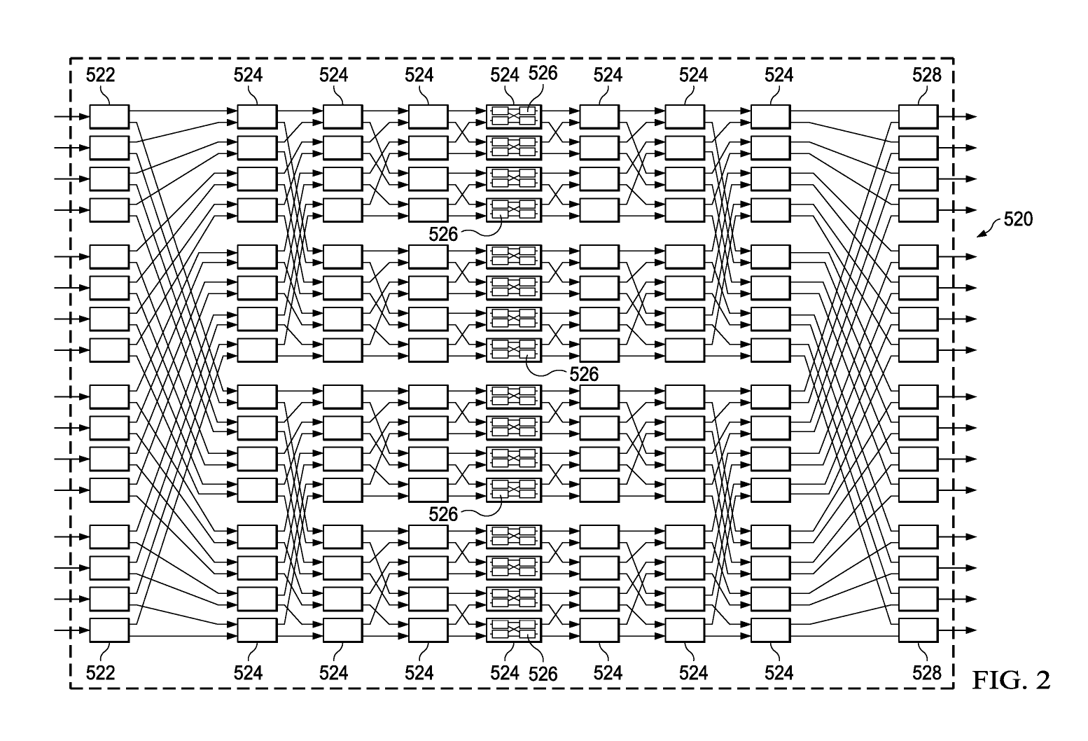

FIG. 2 illustrates a 192 cell indirectly addressable HDBE switching matrix 520. Input cells 522 receive the inputs, which are switched by switches 524. One switch 524 contains four switches 526. The outputs are organized by output cells 528. The HDBE switch has path-to-path connection interactions which involve the planning of a given input-output connection in the context of the other input-output connections. In a synchronous application without random pre-existing paths, the set-up algorithm is applied. Simple algorithms may lead to a small residual amount of blocking, because they do not always place all the connections, which involves feedback to the overall fabric control system, slowing the switch responses. A more sophisticated algorithm with re-tries avoids this problem, but may be slower. In one algorithm, only each 2×2 cell may receive and switch a single optical signal—either as a cross or a bar. A second optical signal cannot be applied to the same cell to use the other cross or bar connection, for good control of optical crosstalk.

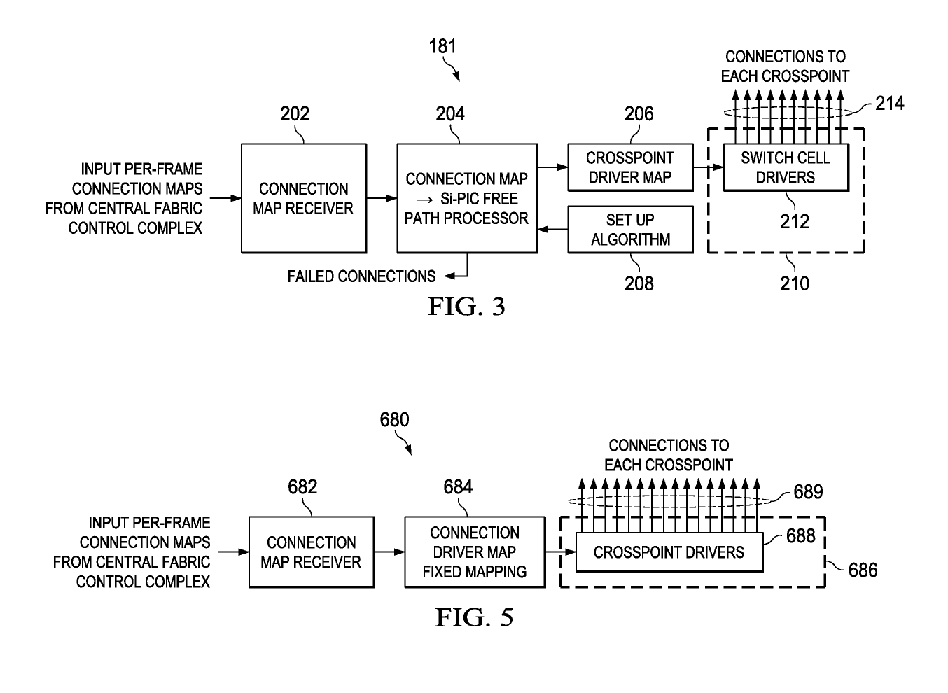

FIG. 3 illustrates a control module 181, which may be used, for example, to control switching matrix 520. Control module 181 includes connection map receiver 202, which receives an input per-frame connection map from an address bus when the contending requests on that bus have been resolved. When a three stage switch is used, the address bus may be received from a central control complex. On the other hand, for a directly addressed deterministically routed matrix switch, the address bus may be from the input sub-group parallel address bus. Connection block 204, which converts the received connection map to a PIC free path processor, uses set up algorithm 208. When one or more of the requested connections cannot be provided, either due to a path not being available or an algorithm timeout, connection block 204 outputs the identity of the failed connection or connections to trigger a retransmission. The connections are output to crosspoint drive map module 206, which determines the crosspoint driver map. Switch cell drivers 212, in block 210, may be intimately associated with the PIC. For example, each switch cell driver 212 may be mounted directly over the PIC it controls, with mechanical and electrical coupling. The switch cell drivers drive the crosspoints using connections 214.

FIG. 4 illustrates photonic switching matrix 660, an ESM PIC topology which uses a larger amount of silicon and a higher crosspoint cell count, but which is strictly non-blocking, has good crosstalk properties, and is directly addressable without a free path search. There are multiple layers 662, 664, 666, 668, 670 of 1×2 switches, coupled to form a binary controlled expansion tree. Switches 668 and 670 are coupled to each of switches 672 and 674 by an intermediate 256×256 orthogonal connection field. Switches 672 and 674 are coupled to switches 676, which are also coupled to switches 678. Also, switches 678 are coupled to switches 679, creating a select tree with one branch of each select being connected to one branch of each expansion tree. Because each switch is a binary 1×2 or 2×1 switch, it may be driven by a single bit of the address, the expansion tree being driven by the output address and the select tree by the input or source address. In the ESM switch shown in FIG. 4, the first stage of the expansion is driven by the most significant bit of the address and the last stage of expansion is driven by the least significant bit. Thus, to link the highlighted inputs expansion block (Input #0) and highlighted output selection block (output #11) the destination address 1011 is applied as a binary 1 to switches 662, 666, and 668/670 and a binary 0 to switch 664. The address is steered to the appropriate cell in each expansion tree by the address of the previous switch in the tree to avoid driving unused cells. A similar process, based on the source address, is used in the selection tree. Thus, the source address used to connect input 0 to output 11 is 0000.

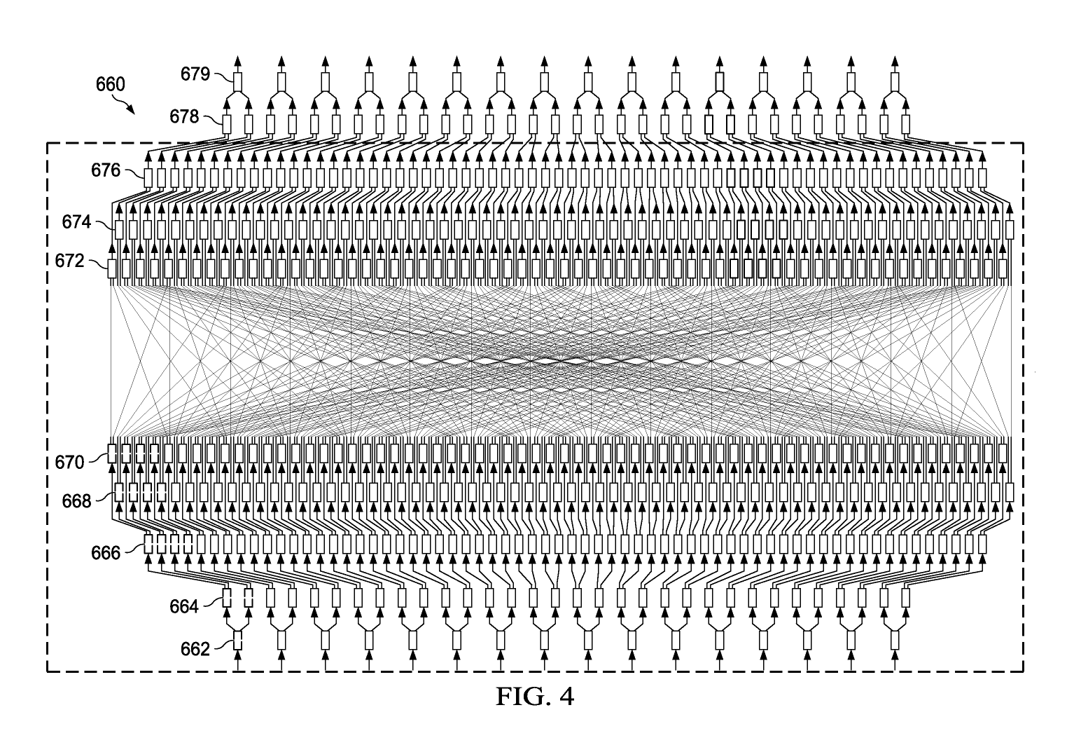

FIG. 5 illustrates control system 680, which may be used, for example, to control switching matrix 660. The input per frame connection maps are received by connection map receiver 682 from an address bus from a central control complex or from the input sub-group parallel address bus, after the contending requests on that bus have been resolved. The connections are mapped by crosspoint driver map 684, a fixed mapping because each connection path is unique, deterministic, and independent of the presence or absence of other connection paths. Crosspoint drivers 688 control the connections to the crosspoints with connections 689. Also, crosspoint drivers 688 are in block 686, which is intimately associated with the PIC, for example mounted over the PIC. There may be no failed connection requests, because the switch PIC is itself directly addressed with no routing algorithm to timeout, and is completely non-blocking. Also, the incoming connection requests have been cleared of self-contention, so no PIC level connection fail line is provided.

A matrixed switch topology involves high port counts with direct addressing. There may be a large number of PICs used. Multiple PICs may be used on a larger area optically connected lithographically defined structure, as a macromodule. A macromodule carries a variety of components in both hybridized and monolithic forms to implement a larger port count matrixed switch, provide polarization-agnostic operation from single polarization technology through polarization-diversity, and incorporate optical amplification to offset PIC and other optical path losses. Additional details on macromodules are further discussed in U.S. patent application Ser. No. 14/710,272 filed on May 12, 2015, and entitled “System and Method for Photonic Switching,” which this application incorporates hereby by reference.

A macromodule may be used. The macromodule carries a number of PICs (for example from two PICs to 32 or more PICs). The macromodule may have a much larger port count by using multiple PICs. Functions such as polarization splitters, rotators, and combiners may be used for polarization agnostic switching. Also, amplification may be used to offset the loss. PIC controllers customized to the switching PIC topology may be mounted directly to the switch PICs, and additional electronic controllers may be hybridized on to the macromodule for SOA control, to provide a system level macromodule control and maintenance interface, or for other purposes. Also, the use of macromodules increases precision in the optical path lengths on the substrate. This is especially important when polarization diverse paths are used, because a different delay on the paths creates polarization-induced skew, which affects the individual symbols of the data stream, because a variable portion of the symbol stream, depending on the actual polarization, is on each of two diverse paths. When the delays are different, the symbols, when recombined, start to partially overlap their neighbors, leading to inter-symbol interference. For a 100 Gb/s signal sent at 25 Gb/s, the polarization diversity skew is a small portion of the symbol period, which is 40 ps. When the polarization diversity skew is 20% of the frame period, this is 8 ps, during which time light can travel 0.16 cm in glass at 0.02 cm/ps, for a transmission distance tolerance of 0.16 cm. This may be achieved using lithographically defined interconnect. Also, the lithographic definition of path lengths facilitates the paths to be tightly length controlled. The differences in path length from any switch input to any switch output should not exceed a pre-defined percentage of the inter-packet or inter-contain gaps, or the gaps become too small for detection of container boundaries at the destination peripheral.

The macromodule may carry multiple PICs to build up an array, provide interconnect between the PICs and the rest of the system, and integrate the polarization components and power splitters and combiners. It also places amplifiers, for example polarization semiconductor optical amplifiers (SOAs), in pairs, which are inside a polarization diverse path. Alternatively, erbium doped waveguide arrays (EDWAs) could be used.

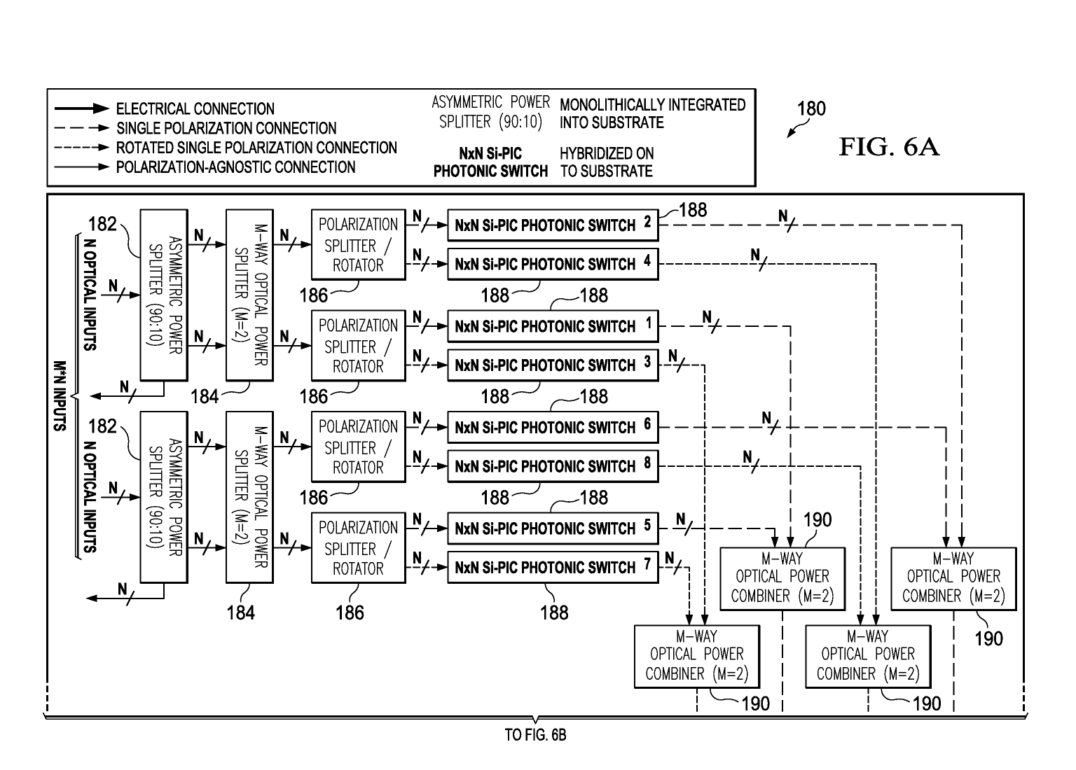

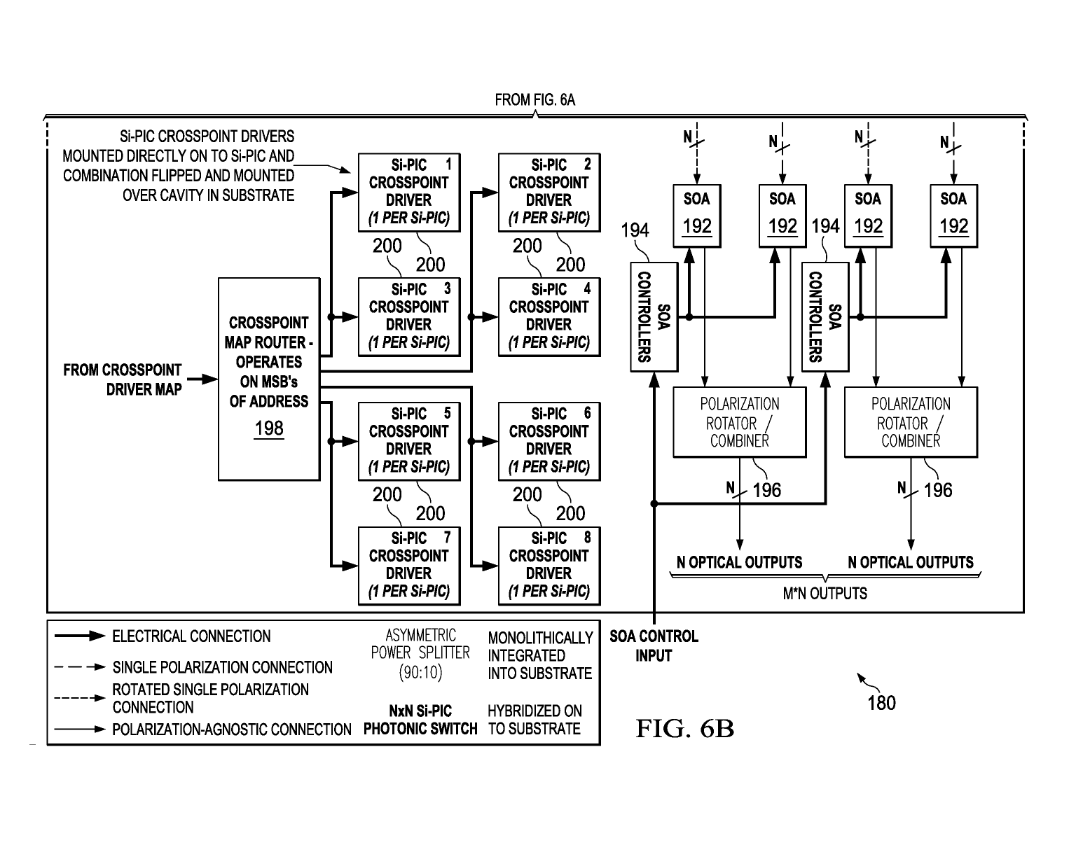

FIGS. 6A-B illustrate a photonic switching macromodule 180. Photonic switching macromodule 180 uses eight hybridized single polarization PICs 188, which are N×N PIC switches. Photonic switching macromodule 180 is a low loss, low skew, polarization agnostic photonic switch with twice the throughput of a single polarization PIC and four times the throughput of an equivalent complexity polarization agnostic PIC. Also, macromodule 180 has a port count of M*N×M*N, where M is the array size (in this example M=2) and N is the output port count for a PIC. The macromodule optical path includes hybridized and monolithic devices, as indicated in FIGS. 6A-B.

M*N inputs enter the macromodule and are received by M*N 90:10 power splitters 182, monolithically integrated on the substrate. 10% of the input optical power is tapped off and fed to a phase comparator, which compares the incoming signal phase with the local switch frame timing, and determines the incoming phase errors, which are fed back to correct the sources. The remaining optical power is fed to power splitters 184. Power splitters 184 are balanced M-way optical power splitters, for example two way monolithic splitters. The split light is fed to 2*M*N polarization rotators and splitters 186, each of which produces two optical outputs both polarized in the optimized plane for improved PIC operation, one signal having also been rotated by 90 degrees.

The output optical streams are fed to 2*M² (eight) N×N hybridized PIC photonic switches 188. The crosspoint driver map is fed from the contention-resolved connection request bus directly to crosspoint map router 198, which operates on the most significant bits of the addresses. The connection addresses constituting the PIC cross-connect map are routed to PIC crosspoint drivers 200, which drive the PICs. There is one PIC crosspoint driver per PIC. The PIC crosspoint drivers are directly mounted on the PIC to facilitate electrical connections between the individual switch cells of the switch matrix PIC and PIC controller controlling those cells.

The switched outputs are then combined by four groups of N M-way optical power combiners 190, where M=2, and fed into SOAs 192 for amplification to compensate for losses, for example in the power splitter, polarization splitter, PIC, power combiner, and not yet reached polarization combiner, as well as other losses, for example from macromodule optical tracks. The SOAs are controlled by SOA controller 194. In another example, a hybridized array of M*N 4×1 photonic switches are used, which are controlled from the PIC select lines. This reduces the loss for higher values of M and allows output port based contention resolution for all values of M. The amplified signals are then combined with signals from the matching polarization by polarization rotators/combiners 196. Finally, M*N optical outputs are output. The polarization diverse paths extend from the input to the polarization rotator/splitter to the output of the polarization rotator/combiner, which is matched for each path pair.

The PICs are mounted optically active surface down on the macromodule, so the optical signals may be readily coupled to the optically active surface of the macromodule. The coupling may be via grating coupling, angled micro-mirror coupling, or by closely coupled waveguide structures. The PIC individual photonic switch cells have individual control. This may be achieved by bonding the PIC controller with its electronic active surface by the PIC's optically active surface before mounting the switch PIC, optically active side down, on the macromodule substrate. To facilitate this, a depression, such as a well or aperture, may be cut in the macromodule substrate under that part of the switch PIC, which is covered by the laminated switch controller, so the switch controller protrudes down into the depression. Electrical connections between the PIC controller and the macromodule substrate may be routed through the PIC.

Multiple components may be used to enhance or complement the capabilities of the photonic switch on a macromodule. An optical interconnect substrate, with a high connection density, relatively low optical loss, a capability to couple into hybridized PICs, and other monolithic and hybridized components, may be on a macromodule, along with external optical connections. Optical traces may cross each other with low loss and low crosstalk. Polarization splitters, combiners, and rotators may be integrated on the substrate. Optical amplifiers may be hybridized SOAs or EDWAs. EDWAs are optically pumped from an external 980 nm source. EDWAs are only weakly polarization dependent or are polarization independent, and may be placed in a polarization diverse region, halving the number of amplifiers. Also, with EDWAs, the source of power, and hence heat, is located elsewhere. Optical power splitters and combiners, including asymmetric power taps for peripheral input signal phase measurement for peripheral phase locking purposes, may be used. Light may be coupled into and out of the macromodule, for example using edge coupling to fibers, expanded bean connectors, and various methods of coupling into and out of hybridized optical components, such as PICs and SOAs. The control electronics for the PIC and SOA may be mounted and interconnected on the components they control.

In a direct addressing switch architecture, a distributed high speed contention detection and resolution system may be used. In a directly addressed switch with deterministic routing, the path addressing from any given input to any given output is independent of the addressing. However, only one input at a time may connect to any given output, so more than one input seeking to reach the same output at the same time creates a contention situation. Contending signaling requests, which are inputs trying to connect associated optical traffic to the same output in the switch, within a sub-group of inputs on each input signaling bus, heading for the same row of PICs, may be detected by detecting colliding addresses on the address stream of each row. The contending addresses are processed. One of the addresses is allowed to continue, while the remaining addresses are blocked by negating their addressing on the bus, and returning a NACK to the source peripheral to indicate the need for later retransmission. The input bus contention resolution has a small delay while this is computed. The input stage contention resolution may be implemented in a hardware state machine. Input contention resolution fully resolves contention between sources within each input bus, but does not resolve contention between different input busses.

Contending output requests between different signaling request busses seeking to use the same output port of the same frame are then resolved. An active selector switch driven off of the column address part of each row address may be used in place of optical combiners. When the controller of this per-column switch receives more than one request per frame for the same output port, it detects a collision. The selector switch selects one of the contending column feeds to be accepted for onward propagation and, via the NACK messaging system, causes a NACK to be sent back to the source peripherals associated with the non-propagated (blocked) requests. There is no need to disable or otherwise modify the contents of the contending PICs, because, even when they output a signal, it is blocked by the column selector switch. The selector switch may have a lower loss than a coupler, especially for higher values of M. The macromodule outputs may have contending requests resolved in a similar process, detecting collisions between macromodule signaling request outputs as the output streams from the macromodules are merged, with each stage of the merging providing an ordered list of intended output ports to be used in the next stage for each frame in the form of an N bit word per sub-group per frame. For N=32 and a 40 ns frame, this word stream has a bit rate of 800 Mb/s when sent serially on a single line. The NACKs from the input bus-based intra-bus contention detection and the output bus based inter-bus contention detection are fed to a messaging block for sending ACKs and NACKs back to the source peripherals.

When a source peripheral attempts to transmit a container, it immediately transmits a connection request specifying the frame number and destination of the container it is assembling to the switch controller in parallel with preparing the container. A pre-determined short period after sending the connection request, sufficient for the switch processor to set up the connection, but not necessarily sufficient for the switch processor to signal back an ACK or NACK, the source peripheral transmits the container and writes that container into a sent container store. Upon receiving an ACK from the switch controller, the peripheral deletes the container from the sent container store. On the other hand, when a NACK is received, the peripheral retransmits the request and the container in sequence.

A matrix switch with high matrix gain is built up from N*N PIC crosspoint arrays. M² PICs are organized as M*M arrays on optical macromodules with M*N inputs and M*N outputs. The macromodules are combined in an array of size P² to create a switch with M*N*P input ports and N*M*P output ports. Table 4 shows the capacities of a switch with N=16, Table 5 shows the capacities of a switch with N=32, and Table 6 shows the capacities of a switch with N=64.

TABLE 4

| | Macromodule | | |
|---|---|---|---|
| Macromodule | array size | | |
| Portion of | portion of | Number of | Overall Switch |
| Matrix Gain | matrix gain | Macromodules | Capacity (port count) |
| 2 | 2 | 4 | 64 × 64 |
| 2 | 3 | 9 | 96 × 96 |
| 2 | 4 | 16 | 128 × 128 |
| 4 | 2 | 4 | 128 × 128 |
| 4 | 3 | 9 | 192 × 192 |
| 4 | 4 | 16 | 256 × 256 |

TABLE 5

| | Macromodule | | |
|---|---|---|---|
| Macromodule | array size | | |
| Portion of | portion of | Number of | Overall Switch |
| Matrix Gain | matrix gain | Macromodules | Capacity (port count) |
| 2 | 2 | 4 | 128 × 128 |
| 2 | 3 | 9 | 192 × 192 |
| 2 | 4 | 16 | 256 × 256 |
| 2 | 6 | 36 | 384 × 384 |
| 2 | 8 | 64 | 512 × 512 |
| 4 | 2 | 4 | 256 × 256 |
| 4 | 3 | 9 | 384 × 384 |
| 4 | 4 | 16 | 512 × 512 |
| 4 | 6 | 36 | 768 × 768 |
| 4 | 8 | 64 | 1024 × 1024 |

TABLE 6

| | Macromodule | | |
|---|---|---|---|
| Macromodule | array size | | |
| Portion of | portion of | Number of | Overall Switch |
| Matrix Gain | matrix gain | Macromodules | Capacity (port count) |
| 2 | 2 | 4 | 256 × 256 |
| 2 | 3 | 9 | 384 × 384 |
| 2 | 4 | 16 | 512 × 512 |
| 2 | 6 | 36 | 788 × 788 |
| 2 | 8 | 64 | 1024 × 1024 |
| 4 | 2 | 4 | 512 × 512 |
| 4 | 3 | 9 | 768 × 768 |
| 4 | 4 | 16 | 1024 × 1024 |
| 4 | 6 | 36 | 1536 × 1536 |
| 4 | 8 | 64 | 2048 × 2048 |

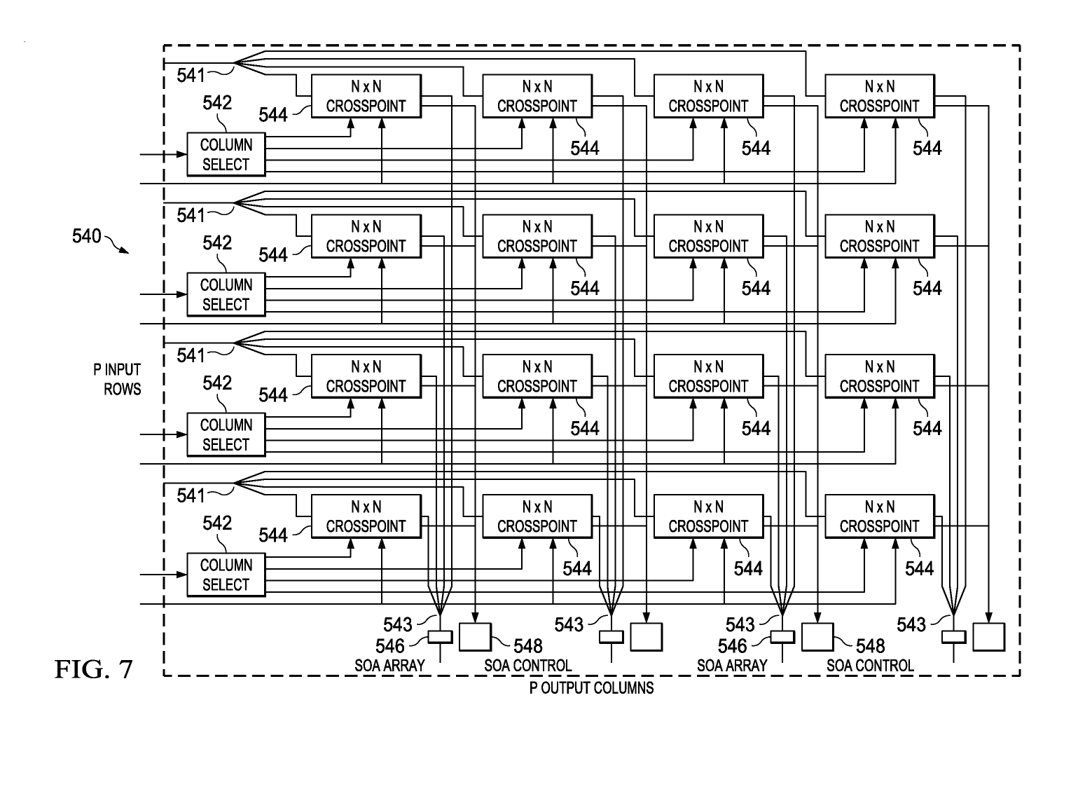

An example photonic switching structure has M=4 and P=2. For a 32×32 PIC, this yields a 256×256 photonic switching fabric. FIG. 7 illustrates a high level view of photonic switching fabric 540, with an array of 16 N×N PIC matrix switches 544. Power splitters 541 are used to split the input optical streams, while power combiners 543 are used to combine the output optical streams. In another example, 4×1 switches are used and output column contention resolution is used. Column selectors 542 are used to select the column for to be switched. SOAs 546, which are controlled by SOA controllers 548, are used to amplify the outputs to compensate for losses.

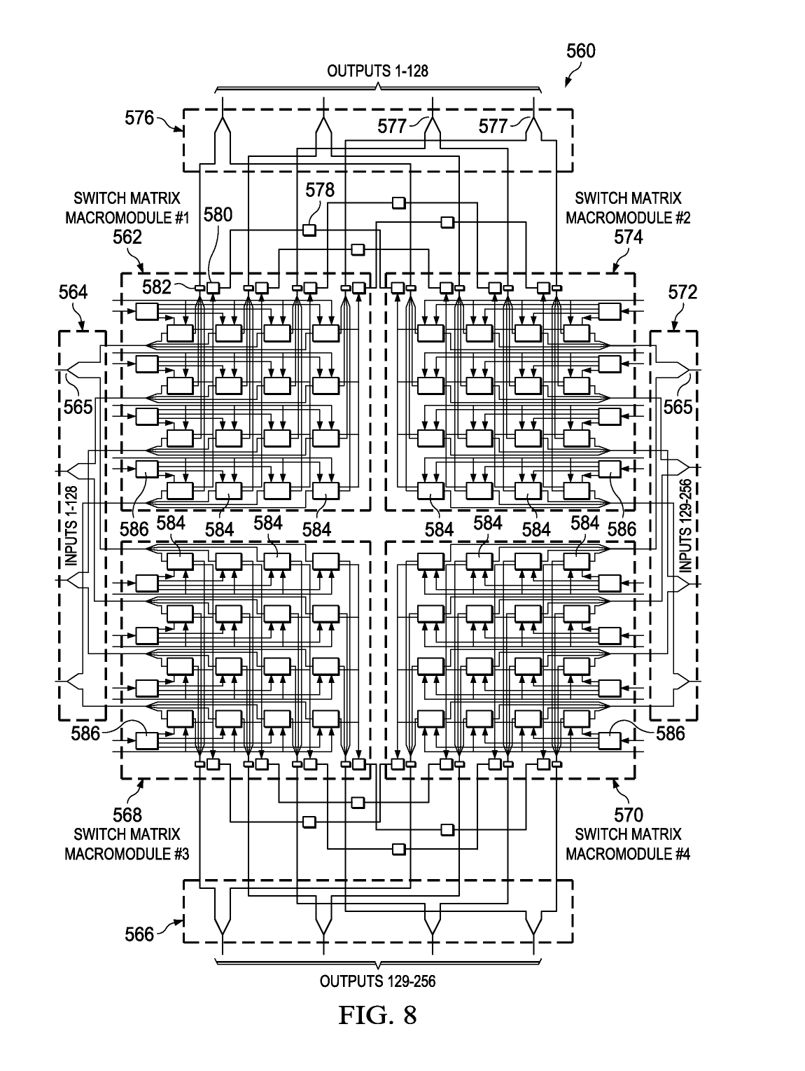

FIG. 8 illustrates a 256×256 photonic switching structure 560. The switch inputs are split with half of the inputs (128 inputs) going into input module 564 and the other half of the inputs going into input module 572. Similarly, the outputs are split with half of the outputs coming from output module 576 and the other half of the outputs coming from output module 566. The macromodules 562, 568, 570, 574 include PIC modules 584, power splitters 586, SOAs 580, and SOA controllers 582. Column selectors 578 are used for selecting the PIC column. The connectivity of the switching module is left-to-top, left-to-bottom, right-to-top, and right-to-bottom. The inputs are split by 1:2 power splitters 565, before reaching the macromodules, and the outputs are combined by 2:1 power combiners 577, after being output from the macromodules. Alternatively, 4×1 active switches on the macromodule and 2×1 active switches between the macromodule outputs may be used, facilitating the use of output column contention detection and resolution.

In another example 1:4 power splitters and 4:1 power combiners are used, and array has P=16, for a port count of 512×512. Again the combiners can be replaced by controlled photonic 4×1 switches allowing output column contention detection and resolution to be applied through control of those switches.

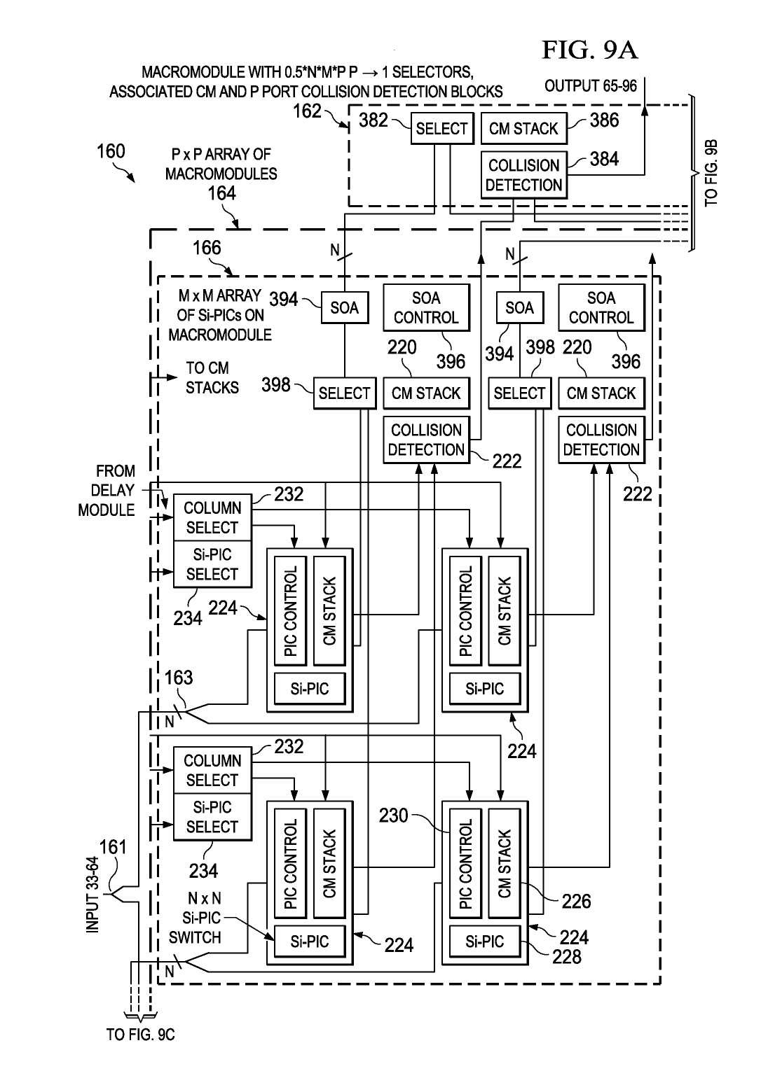

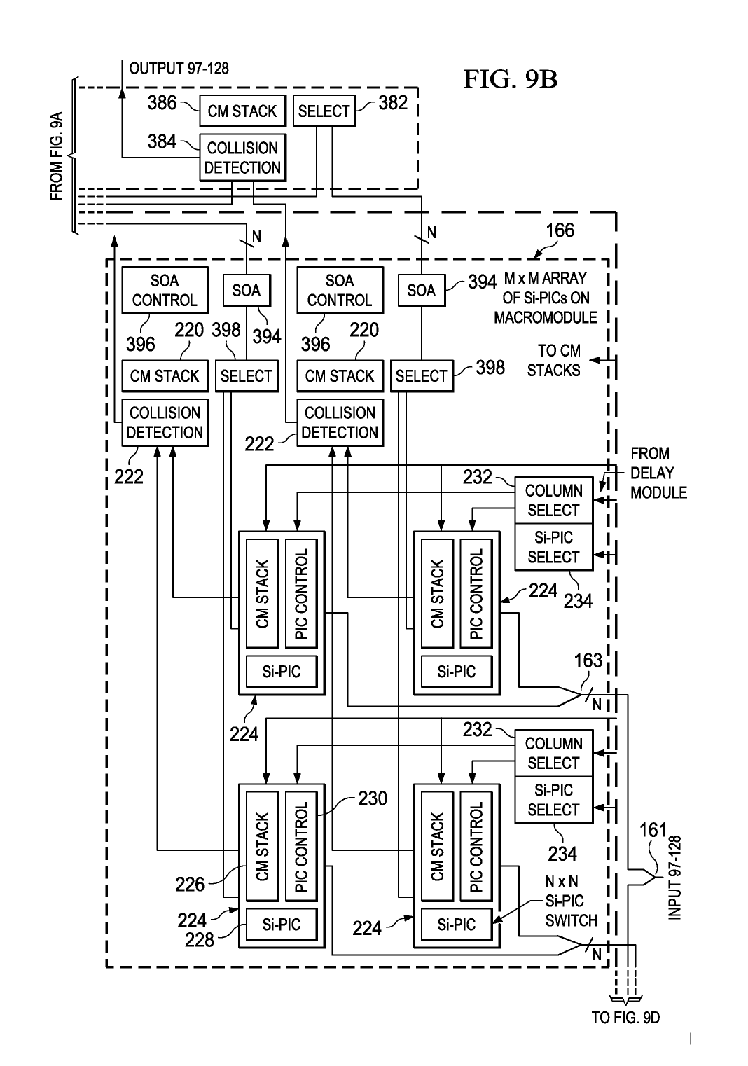

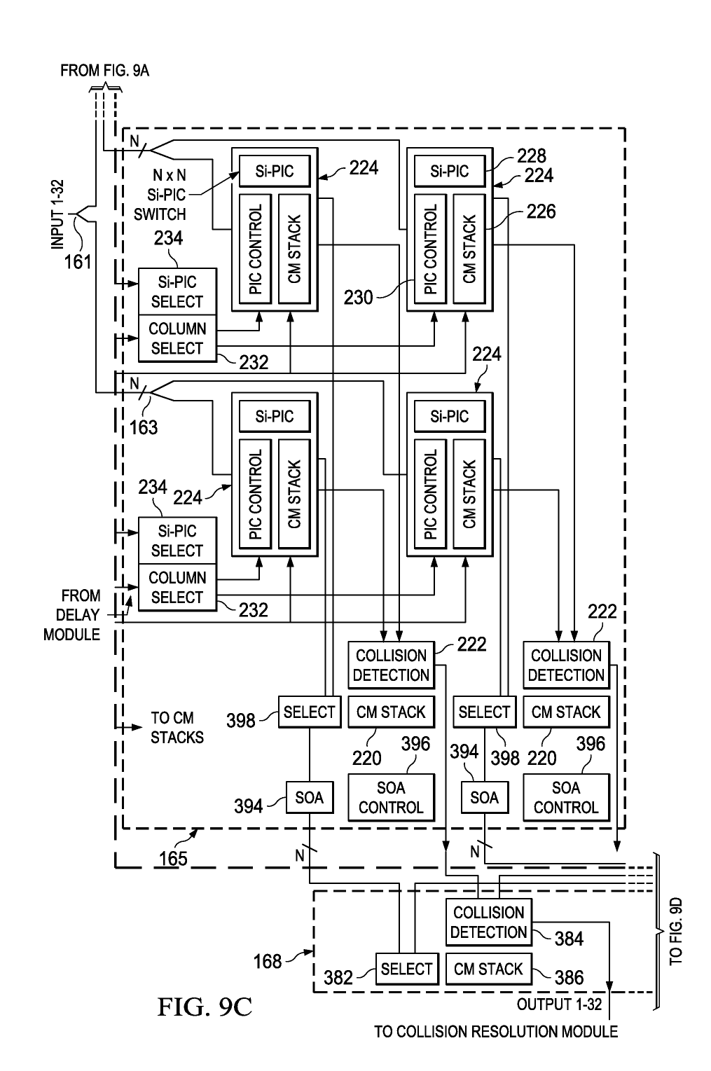

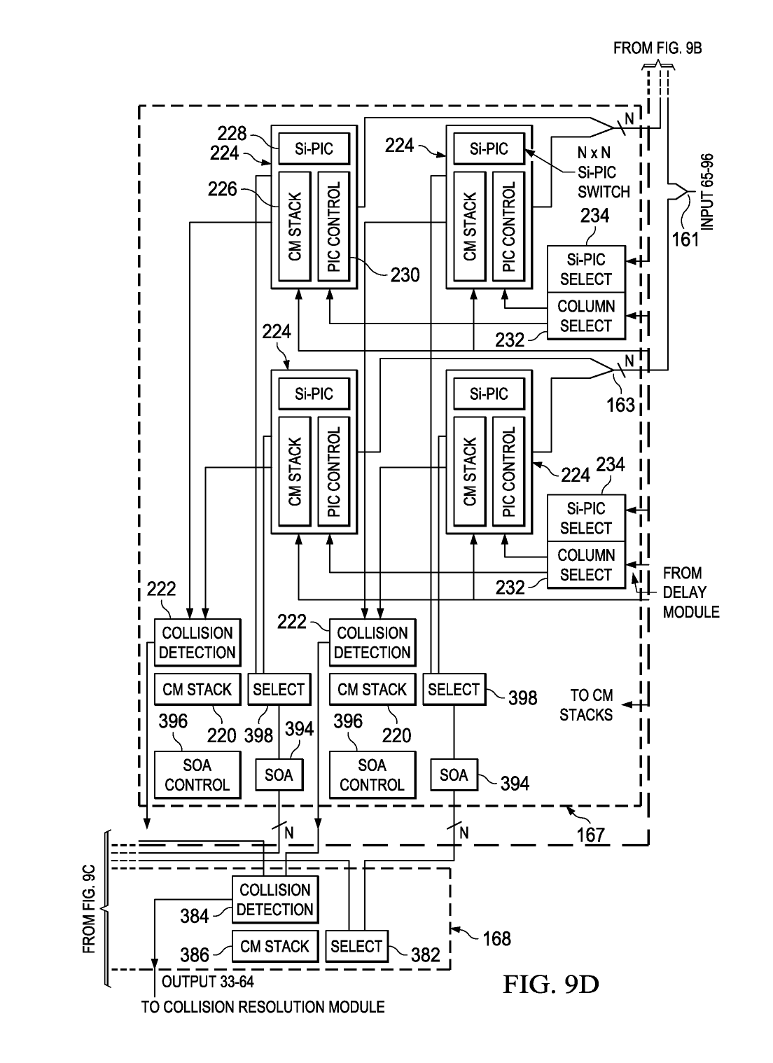

FIG. 9 illustrates an example photonic switching module using a similar multi-macromodule structure to FIG. 8, with a macromodule capacity gain of P=2, active switched output selection, and output contention resolution. FIGS. 9A-D illustrate photonic switch fabric 160, a scalable, fast, and directly controlled macromodule based photonic switching structure which may be controlled by direct addressing and distributed contention resolution. Because P=2, this is a 2×2 array with four macromodules 165, 166, 167, and 169. The inputs are split by power splitters 161 before reaching the macromodule, and again by power splitters 163 on the macromodules. A macromodule includes four PIC nodes 224, where a PIC node contains PIC 228, CM stack 226, and PIC controller 230. A macromodule also contains a set of selectors in the rows, with PIC selector 234 and column selector 232. Also, the macromodules contain a set of column collision detectors for each row, for example output block contention detection and resolution 395, containing collision detector 222, CM stack 220, and output row selector 398. Also on the macromodules, for each output of each column, there is an SOA 394, which is part of an SOA array, and is controlled by an SOA controller 396.

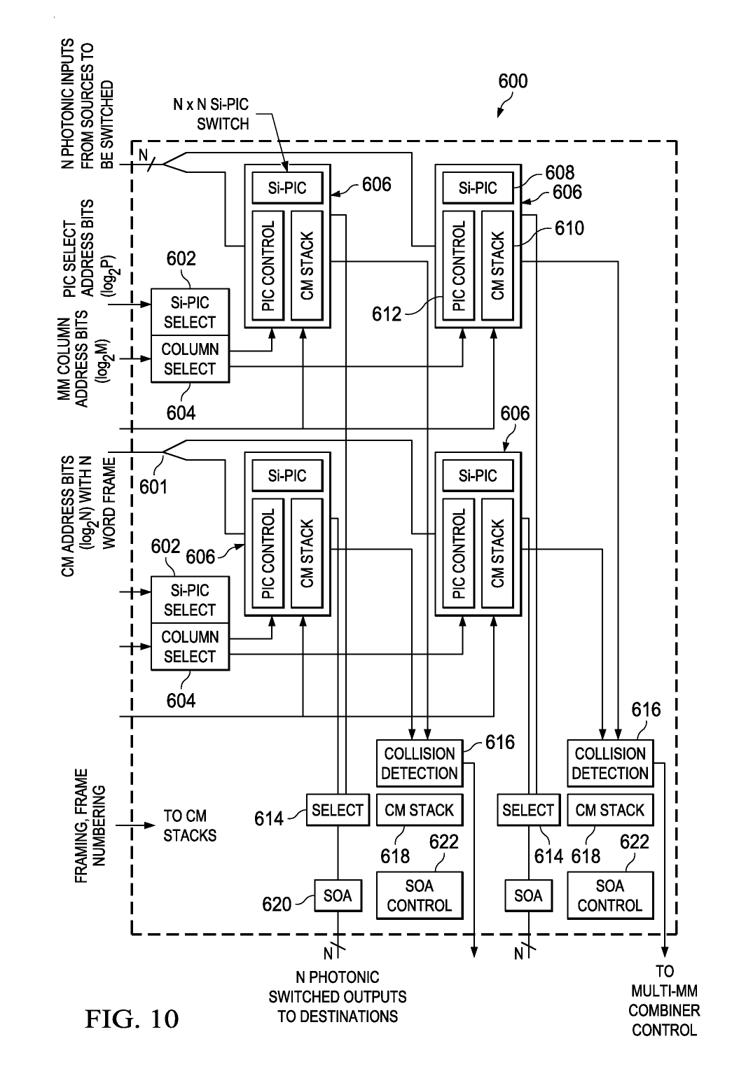

FIG. 10 illustrates a single polarization photonic switching macromodule 600. The macromodule implements a 2×2 array of PIC space switches or polarization pairs of space switches with advanced timing of the switch set up ahead of the arrival of the traffic. The connections to be made are fed into address ports of the macromodule, with one port per row of the macromodule, or pair of rows for polarization diverse macromodules. These connections are already contention-resolved for intra-bus contention, which is when more than one peripheral in the group on a bus requests a particular output in a given frame. Some bits of the address (1 in this case) are used for macromodule selection and some bits of the address (1 in this case) are used for column selection for determining which macromodule of the multiple macromodules on an address bus (two macromodules in this example), and which PIC in the row of that bus is used, based on the output address. Column selector 604 selects whether this macromodule or another macromodule is to communicate into the column used, and PIC selector 602 selects the PIC when this macromodule is to be used in a specific connection. Thus, the column selector may accept additional address bits and act as a macromodule selection module as well, causing the address bus on its macromodule to be prevented from writing an address to PICs when the address is out of the output port range handled by its macromodule. In this case, the connection is being handled by a companion macromodule or macromodules, for example the other macromodule fed from the same bank of splitters.

When an input requests an output address within the range of the macromodule outputs, the column selector causes that address to be written to the appropriate PIC node interfacing from that row to the appropriate column. The macromodule contains PIC modules 606, which contain PIC 608, PIC controller 612, and CM stack 610. The PIC controller is an ASIC which controls the cells of the PIC. The PIC controller maps the connection requests to action cell activation, based on the switching topology. The CM stack stores the connections for several frames. The macromodule also contains power splitters 601, which split the input optical streams among the PICs.

Because connection requests are written before the connections are made, the delay between the two connection mechanisms causes the connections to be stacked up in the connection memory stack until the appropriate system frame number arrives, when the connection is made. For long or moderate length frames, this may be the next frame. However, for very short frames, for example 40 ns frames, a few frames worth of connections may be stacked, while frame contention is resolved. This is not problematic, because the time for this process is much shorter than the time to assemble and process a container. Thus, contention events are detected and resolved before the act of switching occurs. The results of the contention resolution, in terms of blocked connections, may be later returned to the peripherals, which have used a send before ACK or NACK approach, in which the peripherals store copies of sent containers until an ACK or a NACK is received. If an ACK is received, the peripheral deletes the stored container, and if a NACK is received, the peripheral retransmits the stored container, and then re-stores it. This avoids delays from waiting for the ACK before the initial transmission, because the time of flight of that ACK back to the furthest peripheral can be 2.5-5 μs (or 500 m to 1 km of fiber delay).

The input port intra-bus contention resolved connections are fed to the CM stack of the appropriate PIC for use in a future frame. The PIC node, upon receiving a connection map for a frame, immediately writes out the output ports it will be requesting in the future frame to that frame's collision detector 616. The collision detector 616 is associated with CM stack 618 and output row selector 614. The macromodules also include SOAs 620, which are controlled by SOA controllers 622. In one embodiment, the PIC node CM stacks read out the outputs they will be using in a fixed order as an N bit word, where N is the number of PIC output ports. For a 32×32 PIC, the output word is 32 bits long, and may be serial, parallel, or a combination. The word may contain a value of 1 for used outputs and a value of 0 for unused outputs, or vice versa. For example, for a 32 output PIC where ports 1, 5, 8, 12, 13, 17, 22, 26, and 27 are being used, the word might be 10001001000110001000010001100000. This 32 bit word is generated once per frame. For a 40 ns frame there is an 800 Mb/s rate stream. The collision detection block runs this word from each of its column input feeds from different rows through a logic gating function, which looks for a 1 in the same place in these words, indicating a collision. For example, when a second row is intending to output ports 2, 6, 9, 10, 13, 15, 17, 19, 26, 28, and 31, it generates 01000100110010101010000001010010. Table 7 shows a comparison of these two words. When the input collisions are resolved, they are replaced with the identity of the surviving connection (1 or 2), and this becomes the connection map for the associated selector CM stack for that frame.

TABLE 7

| | |
|---|---|
| Collision Detection Input | |
| 1 | 10001001000110001000010001100000 |
| 2 | 01000100110010101010000001010010 |
| Collision Detection Output | 120012012201C010C02001000C120020 |

When the overall switch frame number, which may be a recycling frame number with a limited length of sequence, reaches a matching frame number for the given set of CM entries in the CM stack, they are applied to the PIC controller with sufficient lead time for the PIC controller to complete its computation. Then, on a frame strobe from the overall switch timing, they are loaded into the PIC photonic switching cells, with the timing of the change over aligned with the inter-container gap (ICG) of the incoming traffic, so the connection map is put into effect for a new frame. When the PIC controller uses a long period of time for the computation, for example with an HDBE topology and very short frames, there may be an advanced read timing on the CM stack for the PIC controller to have sufficient compute time. In another example, the CM stacks are read early to the PIC controllers, and the PIC controller's stack completes photonic cell drive maps at the appropriate frame time. This uses significant memory, because the PIC control maps may be several orders of magnitude larger than the connection maps with some topologies. For an EAS switch, the PIC control map may be produced very rapidly, for example on the order of tens of nanoseconds.

When the frame number for a specific set of connections is reached, those connections are set up on the PICs. There will be no contention on the outputs of a single PIC, because this has been resolved on the input address bus collision detection. More than one PIC may attempt to provide an output to the same macromodule output. However, only one will succeed, because the output selector of each column selects the output of the successful PIC and blocks the others. The source of the other traffic contending for that output destination in that timeslot will receive a NACK, and initiate a retransmission.

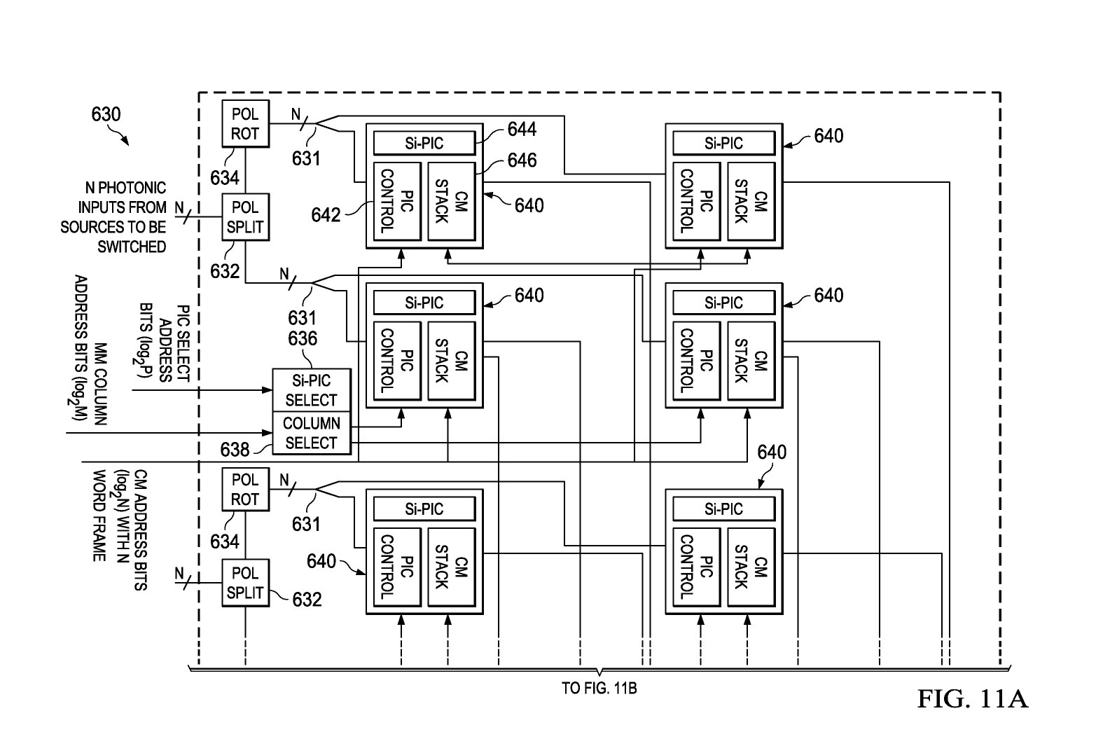

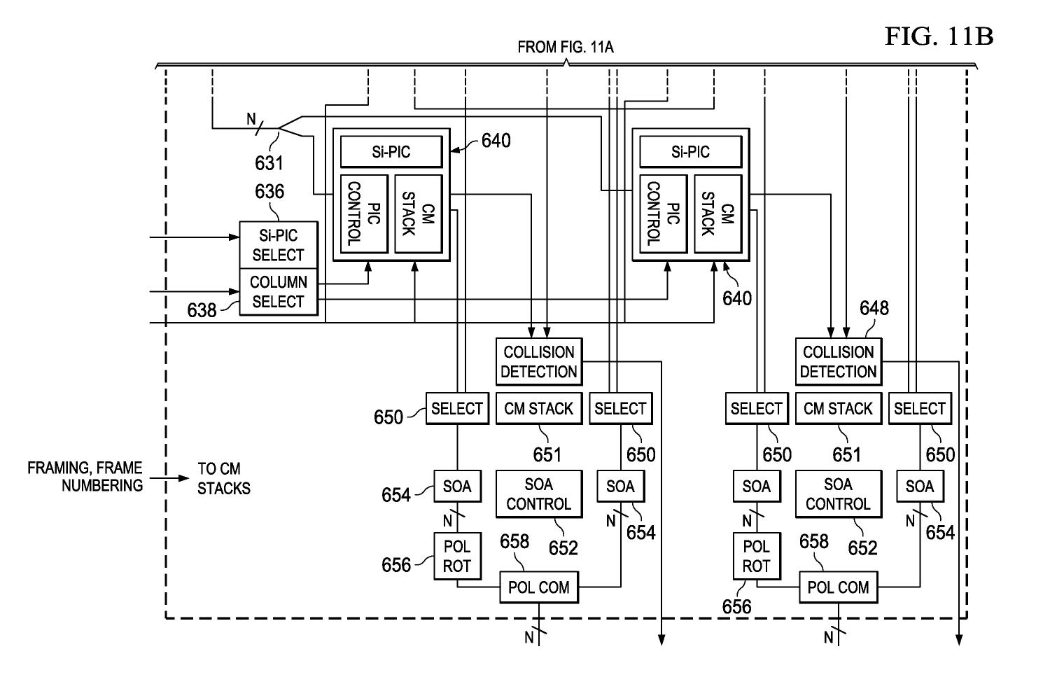

FIGS. 11A-B illustrate macromodule 630 for a polarization diverse switching module. The column selection is done by column selector 638, and PIC selection is done by PIC selector 636. The input optical streams are split by polarization rotators 632, which output two optical streams having orthogonal polarizations. One of the optical streams is polarization rotated ninety degrees by polarization rotator 634, so the two optical streams have the same polarization. These optical streams are power split by power splitters 631, and directed to eight PIC nodes 640. A PIC node contains PIC 644, PIC controller 642, and CM stack 646. The switched optical streams are directed to collision detectors 648 for output row collision detection. The approved optical stream is selected by row selector 650. CM stack 651 stores the connection maps. The selected optical streams are amplified by SOAs 654, which are controlled by SOA controller 652. One stream is polarization rotated ninety degrees by polarization rotator 656. Finally, the polarization diverse streams are combined by polarization combiner 658 to form the output optical stream.

FIG. 12 illustrates photonic switching structure 740, where P=2 and M=2. Four 2×2 macromodules each carry four PIC pairs, for a switch capacity of 4N, where N is the number of ports per PIC. For 32×32 PICs, the switch has a capacity of 128×128. Four macromodules 746 are connected to power splitters 742, where the inputs are received and split. Macromodules 746 include an array of PICs, polarization combiners, polarization components, and amplifiers. There are four input groups, with the first input group receiving inputs 1 to N, the second input group receiving inputs N+1 to 2N, the third input group receiving inputs 2N+1 to 3N, and the fourth input group receiving inputs 3N+1 to 4N. Selector modules 754 with selectors 756 are used for macromodule selection.

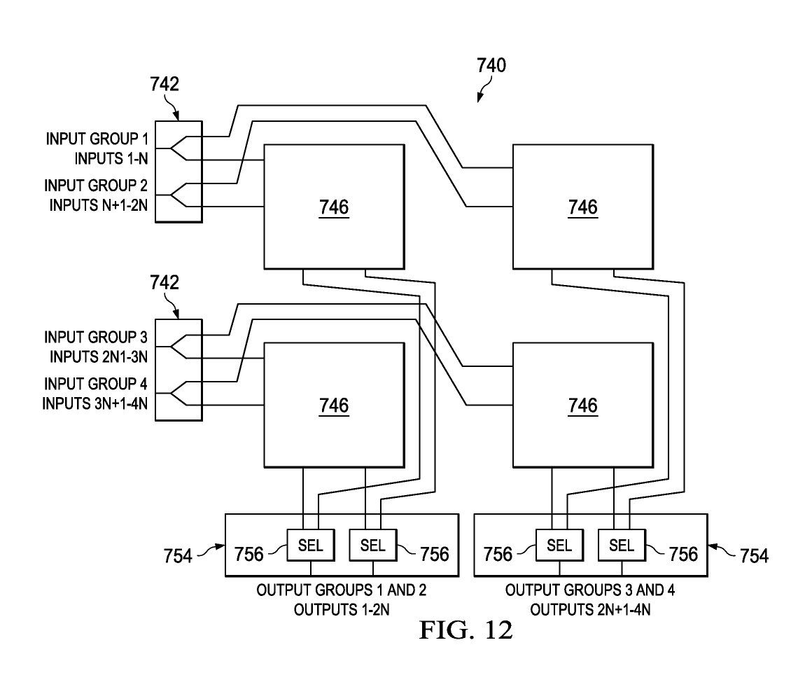

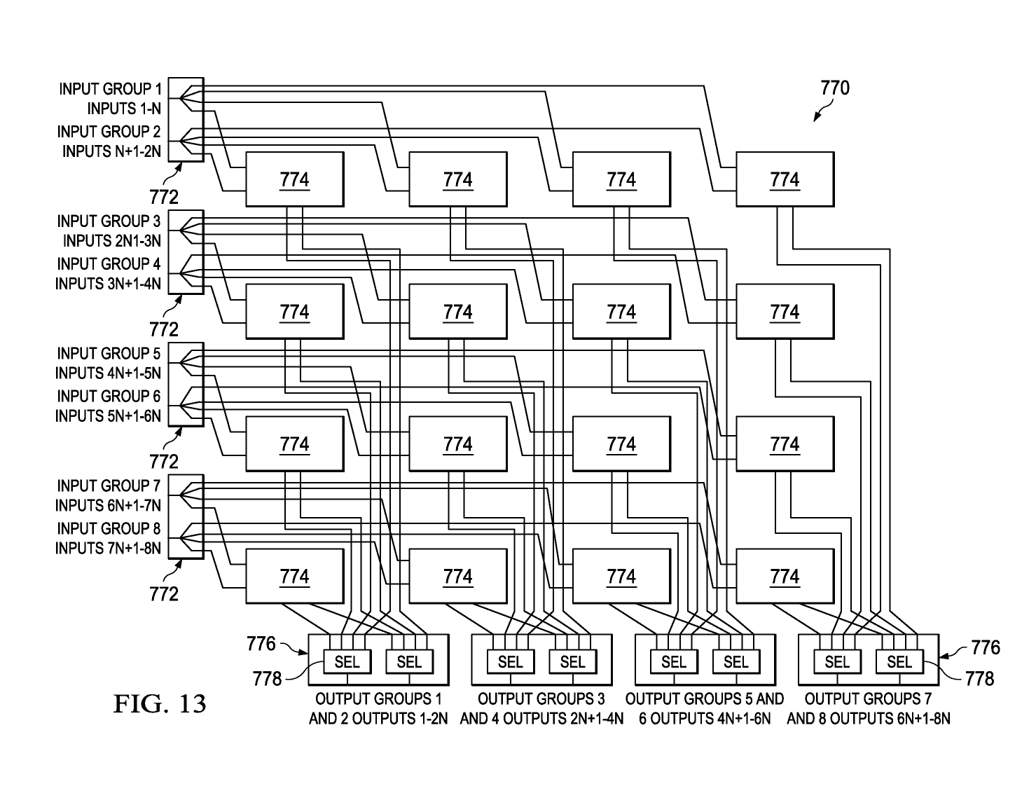

FIG. 13 illustrates a higher port count photonic switching structure 770, where P=4 and M=2. Sixteen macromodules 774 are arranged in a 4×4 grid. The macromodules each carry four PIC pairs for a switch capacity of 8N, where N is the number of input points per PIC. For a 32×32 PIC, this yields a 256×256 switch. The macromodules include an array of PICs, polarization combiners, polarization components, and amplifiers. Eight input groups are received in optical power splitters 772, which split the inputs four ways. The selection is performed by selector modules 776 which contain selectors 778.

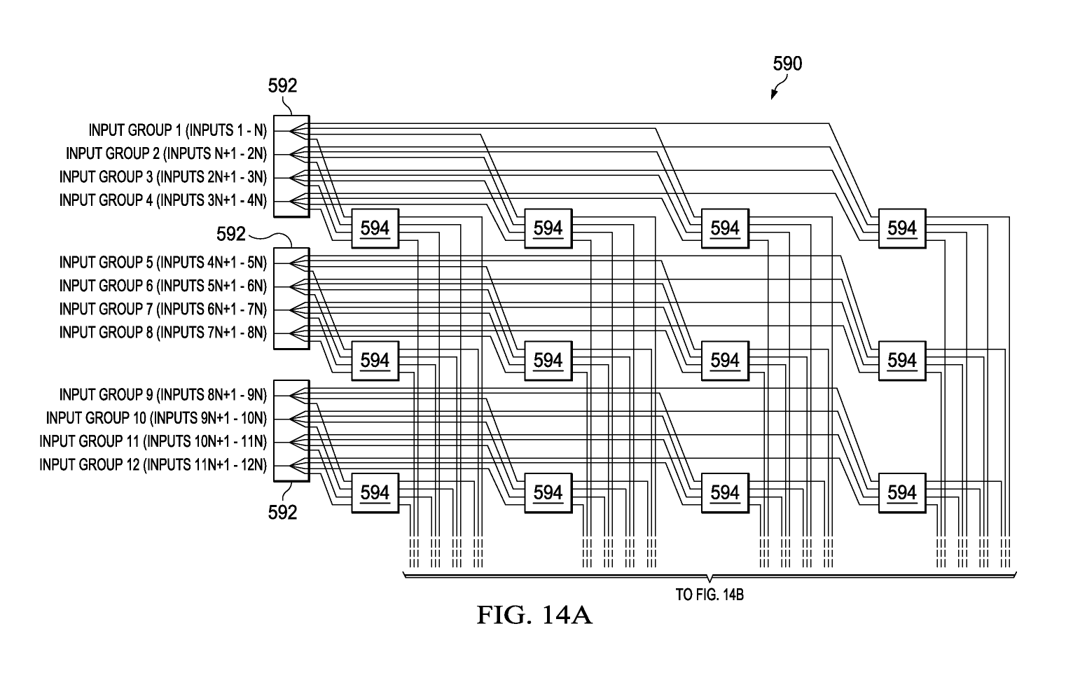

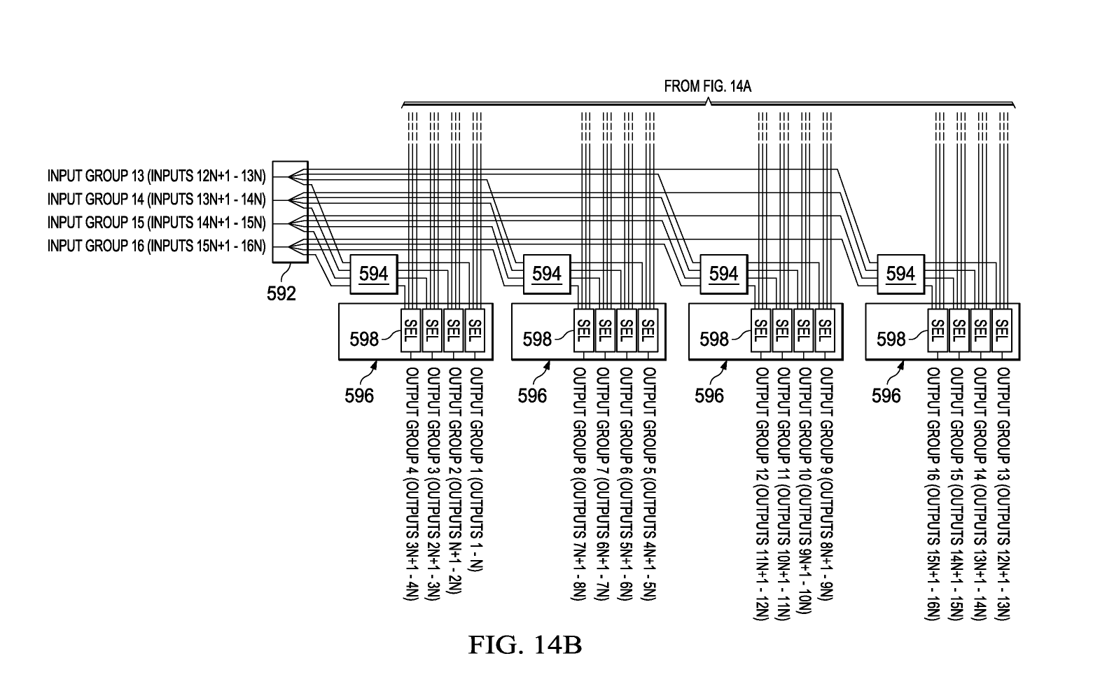

FIGS. 14A-B illustrate an even higher port count photonic switching structure 590, where P=4 and M=4. Sixteen macromodules 594 are arranged in a 4×4 grid. The macromodules include an array of PICs polarization combiners, polarization components, and amplifiers. The macromodules each carry sixteen PIC pairs for a switch capacity of 16N, where N is the number of input points per PIC. For a 32×32 PIC, this yields a 512×512 switch. Sixteen input groups are received in optical power splitters 592, which split the inputs four ways. The selection is performed by selector modules 596 which contain selectors 598. Use of 64×64 PICs results in a 1024×1024 fabric with this topology with large complex macromodules.

The input optical feeds are split into P equal power optical signals by a 1:P passive splitter. Alternatively, an input selector switch driven from the macromodule address bits is used to reduce losses from the optical splitter, especially for a high P. The power split optical signals are fed into P macromodules of one row, each with connectivity to 1/P of the total output ports. Switching involves connecting the input through the right macromodule to obtain the correct output group, and using the macromodule to obtain the correct output within that group.

The overall optical loss is illustrated by Table 8 for a single high gain point of amplification and by Table 9 for two moderate gain points of amplification. Two amplification points results in significantly less dynamic range for the optical power levels throughout the switch, as well as lower SOA optical gains.

TABLE 8

| | | | Optical Power |
|---|---|---|---|
| | | | Level Relative to |
| Block | Source of Loss | Loss | Input |
| Input Splitting Component | Input Coupling | 1 | −1 |
| Input Splitting Component | Power Split Four Way | 6.4 | −7.4 |
| Input Splitting Component | Output Coupling | 1 | −8.4 |
| Switch Macromodule | Input Coupling | 1 | −9.4 |
| Switch Macromodule | Power Split Two Way | 3.2 | −12.6 |
| Switch Macromodule | Polarization Splitting/Combining | 2 | −14.6 |
| Switch Macromodule | Coupling to PIC | 1 | −15.6 |
| Switch Macromodule | PIC Loss | 6 | −21.6 |
| Switch Macromodule | Coupling From PIC | 1 | −22.6 |
| Switch Macromodule | Coupling to SOA | 1.5 | −24.1 |
| Switch Macromodule | SOA Loss | −21 | −3.1 |
| Switch Macromodule | Coupling from SOA | 1.5 | −4.6 |
| Switch Macromodule | Macromodule Tracking Losses | 1.2 | −5.8 |
| Switch Macromodule | Coupling to Selector | 1 | −6.8 |
| Switch Macromodule | Selector Loss | 0.6 | −7.4 |
| Switch Macromodule | Coupling from Selector | 1 | −8.4 |
| Switch Macromodule | Coupling from Macromodule | 1 | −9.4 |
| Combiner Macromodule | Coupling to Combiner Macromodule | 1 | −10.4 |
| Combiner Macromodule | Polarization Splitting/Combining | 2 | −12.4 |
| Combiner Macromodule | Coupling to Selector | 1 | −13.4 |
| Combiner Macromodule | Selector Loss | 1.2 | −14.6 |
| Combiner Macromodule | Coupling from Selector | 1 | −15.6 |
| Combiner Macromodule | Output Coupling | 1 | −16.6 |
| | Total | 16.6 | |

TABLE 9

| | | | Optical Power |
|---|---|---|---|
| | | | Level Relative to |
| Block | Source of Loss | Loss | Input |
| Input Splitting Component | Input Coupling | 1 | −1 |
| Input Splitting Component | Power Split Four Way | 6.4 | −7.4 |
| Input Splitting Component | Output Coupling | 1 | −8.4 |
| Switch Macromodule | Input Coupling | 1 | −9.4 |
| Switch Macromodule | Power Split Two Way | 3.2 | −12.6 |
| Switch Macromodule | Polarization Splitting/Combining | 2 | −14.6 |
| Switch Macromodule | Coupling to SOA | 1.5 | −16.1 |
| Switch Macromodule | SOA Loss | −12 | −4.1 |
| Switch Macromodule | Coupling from SOA | 1.5 | −5.6 |
| Switch Macromodule | Coupling to PIC | 1 | −6.6 |
| Switch Macromodule | PIC Loss | 6 | −12.6 |
| Switch Macromodule | Coupling from PIC | 1 | −13.6 |
| Switch Macromodule | Tracking from Macromodule | 1.2 | −14.8 |
| Switch Macromodule | Coupling to Selector | 1 | −15.8 |
| Switch Macromodule | Selector Loss | 0.6 | −16.4 |
| Switch Macromodule | Coupling from Selector | 1 | −17.4 |
| Switch Macromodule | Coupling to SOA | 1.5 | −18.9 |
| Switch Macromodule | SOA Loss | −14 | −4.9 |
| Switch Macromodule | Coupling from SOA | 1.5 | −6.4 |
| Switch Macromodule | Coupling from Macromodule | 1 | −7.4 |
| Combiner Macromodule | Coupling to Combiner Macromodule | 1 | −8.4 |
| Combiner Macromodule | Polarization Splitting/Combining | 2 | −10.4 |
| Combiner Macromodule | Coupling to Selector | 1 | −11.4 |
| Combiner Macromodule | Selector Loss | 1.2 | −12.6 |
| Combiner Macromodule | Coupling from Selector | 1 | −13.6 |
| Combiner Macromodule | Output Coupling | 1 | −14.6 |
| | Total | 14.6 | |

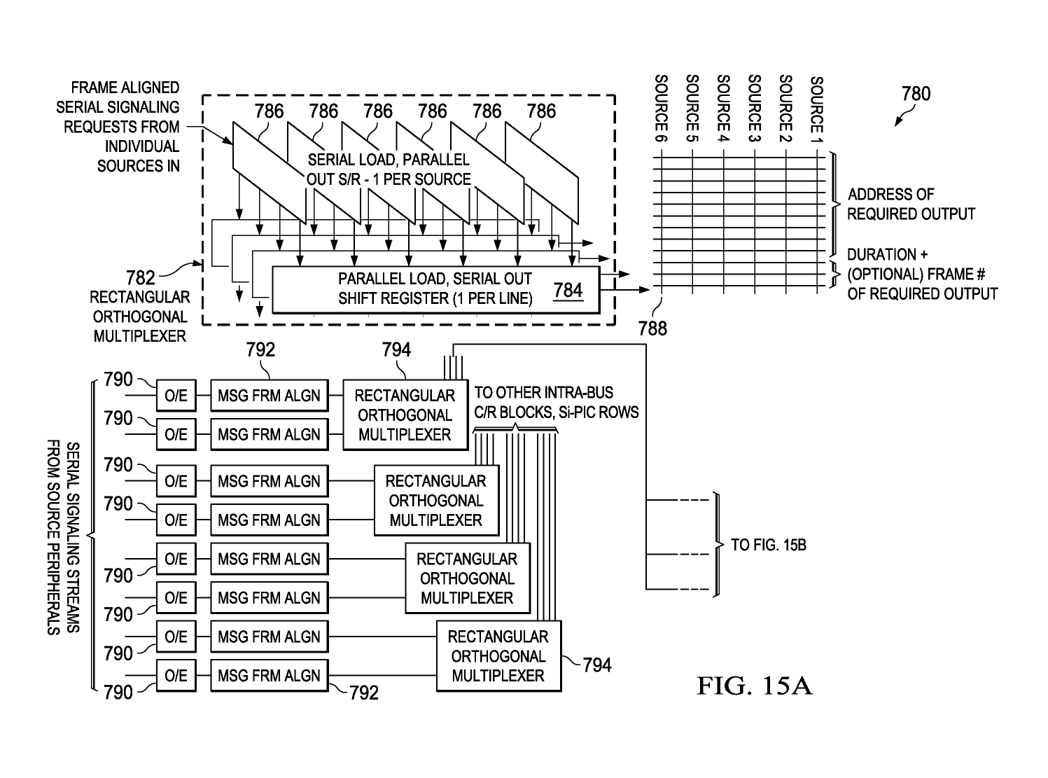

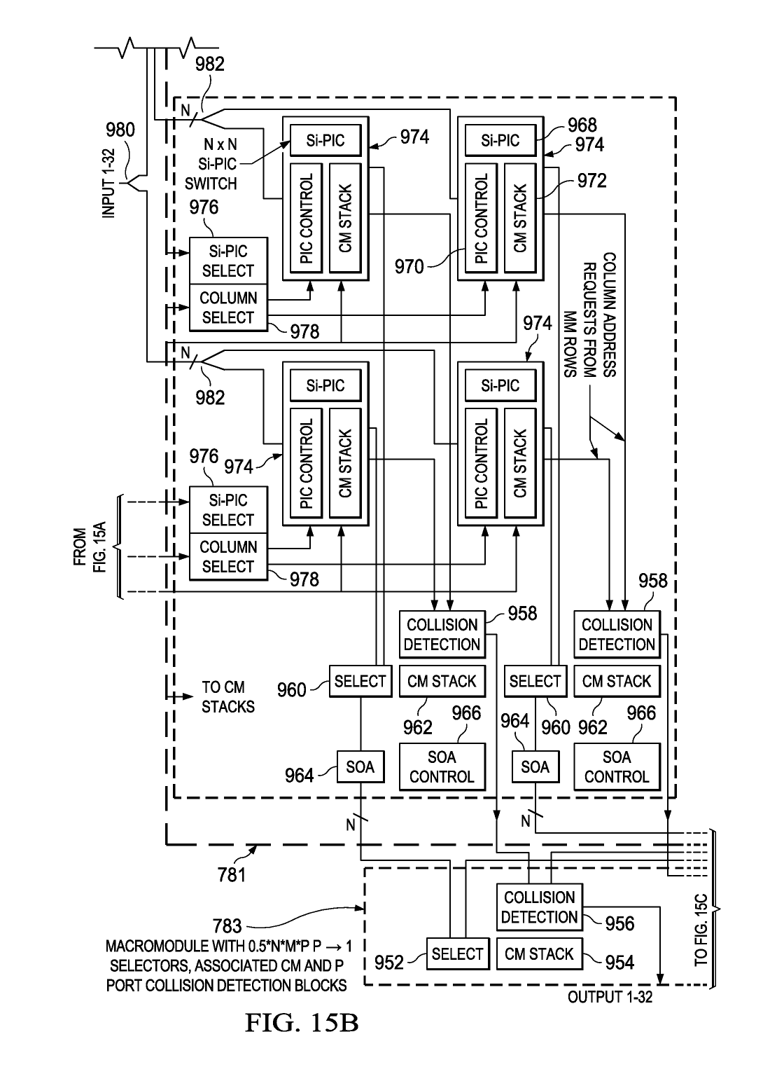

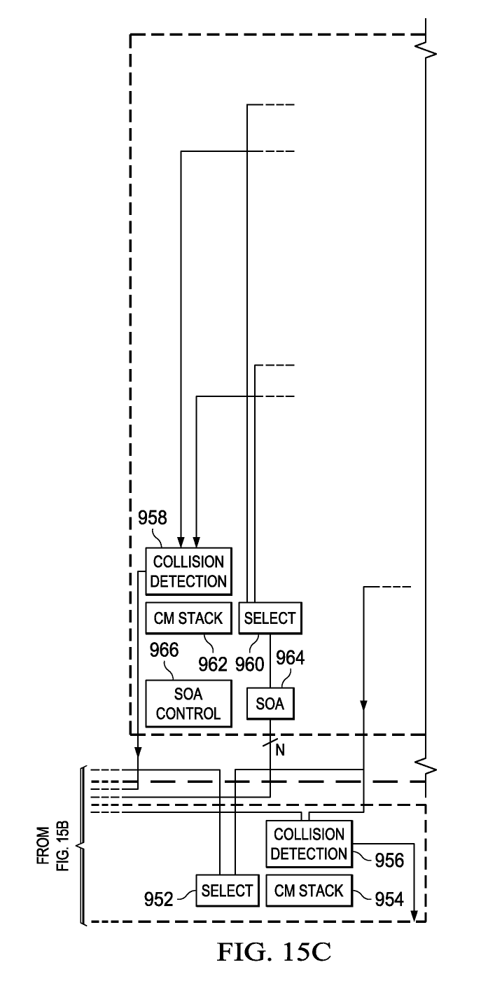

FIGS. 15A-C illustrate system request subsystem 780. Connection requests from the source peripherals are received via serial optical links of medium speed from the peripherals, which carry frame-identified destination requests and durations when concatenation is used. The optical connection request signaling streams from the peripherals are received and converted from optical signals to electrical signals by optical-to-electrical converters 790. The electrical signals are then frame aligned by message frame aligners 792 to the signaling frame rate, which may be the same as or related to the switch fame rate.

The signaling inputs form a group of peripherals of size N, where N is the number of inputs of a PIC, which are frame aligned. The signaling inputs are fed into rectangular orthogonal multiplexers 794, which have R outputs, where R is the number of information bits in a connection request message. The rectangular orthogonal multiplexer takes the N separate serial input streams and produces a single time multiplexed multi-bit address bus which is R bits wide with an N word frame. The source location identity of the input requests is by the timeslot placement within the frame to carry both source and destination addresses. The address length is given by:

Address=log₂N+log₂M+log₂P.

For N=32, M=2, and P=2, the address is 7 bits for a 128×128 switch. For N=32, M=4, bits and P=4, the address is 9 bits for a 512×512 switch. Also, for N=64, M=4, and P=4, the address is 10 bits for a 1024×1024 switch. There may also be three bits for concatenation and 4 bits for cycling sixteen frames or 8 bits for cycling 256 frames.

The rectangular orthogonal multiplexing is achieved by clocking the frame aligned signaling channels from the sources into a parallel array of R bit long shift registers 786 in rectangular orthogonal multiplexer 782. When the R bits of the signaling messages from each source are loaded into the shift registers, they perform a parallel load of their contents into a second array of R shift registers 784, which are each N bits long, and which are connected orthogonally across the N input shift registers. The output from the rectangular orthogonal multiplexer is an N time slot framed signaling bus with a frame rate matching the signaling frame rate of R bits width, where R includes the number of bits to directly address the selected PIC (log₂N), to select a PIC from ach row of M PICs (log₂M), and to select the macromodule to use (log₂P), as well as additional information, such as 4-8 bit cycling frame numbers and a 2-4 bit concatenation length identifier for short containers which may be concatenated in some applications. Alternatively, there is no concatenation, and all requests for a given frame are given a fixed lead time, where the lead time is primarily affected by the speed of the contention detection and resolution system. An address stream is illustrated by block 788.

The address bus PIC address portion is fed to the PIC nodes 974 in switching module 781, while the PIC select module 976 and column select module 978 determine whether a given PIC will be enabled to write the given address of any time slot and into which PIC chip in the row of PICs in the selected macromodule. PIC node 974 contains PIC 968, PIC controller 970, and CM stack 972. The macromodules also contain power splitters 982, SOAs 964, and SOA controllers 966. Polarization-agnostic versions of the macromodules also contain polarization splitters, rotators, and combiners, and a set of duplicated polarization diversity paths and building blocks. The input optical streams are split by optical power splitters 980. When the addresses are loaded into the CM stack of the PIC node, the outputs in the frame are fed to output selector control/contention detector blocks 783, which contain row selector 952, collision detector 956, and CM stack 954. The CM stack of the associated column selector connects the output from the source PIC though to the macromodule output. Switching module 781 also includes row selectors 960, collision detection modules 958, and CM stacks 962.

When two PICs from different rows in a macromodule simultaneously attempt to select the same output, a collision is detected. The collision is resolved by blocking all but one of the requests. The surviving request sets up an entry in the CM stack 954 of row selector 952. Collision detector 956 outputs a similar list of outputs to be used in the switch for the multi-macromodule output merging switching combiner blocks.

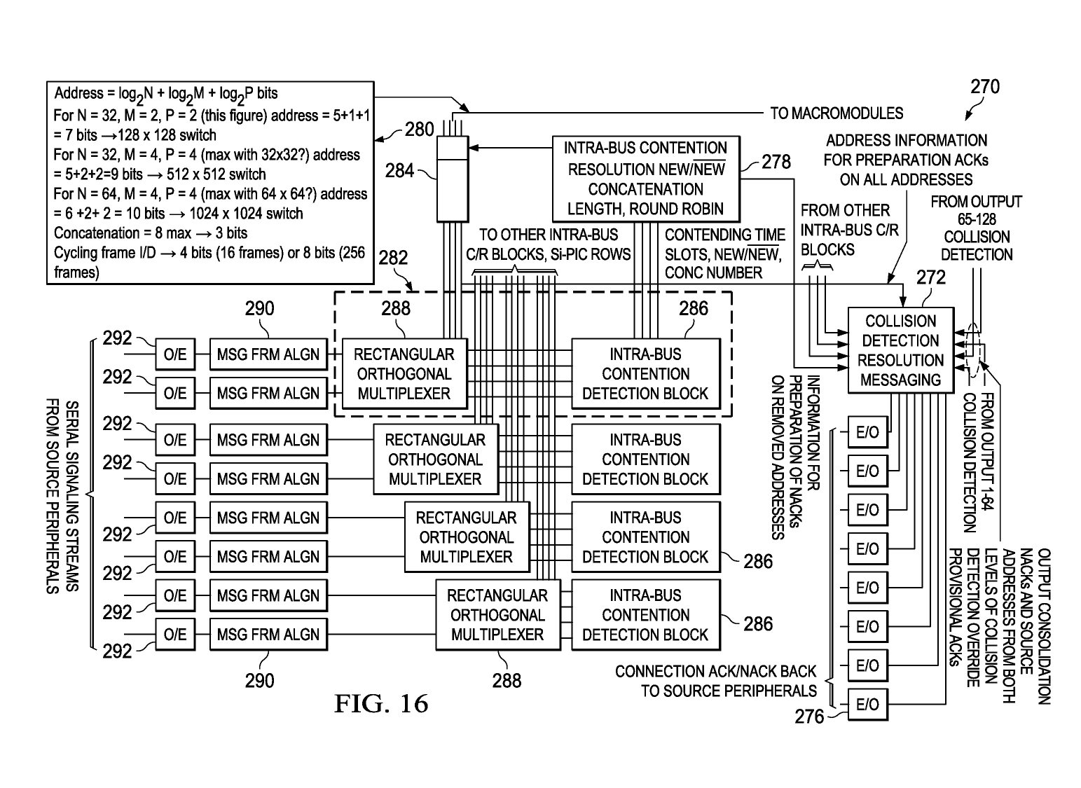

FIG. 16 illustrates the input side component of the output port contention detection and resolution system 270. The input side contention detection and resolution system detects and resolves contending inputs on each connection signaling bus from a group of source peripherals associated with that bus to find which peripherals are requesting the same output connection in the same frame, which would lead to a collision of containers at the output when left unresolved. The input side contention detection and resolution system resolves contention between inputs on the same bus.

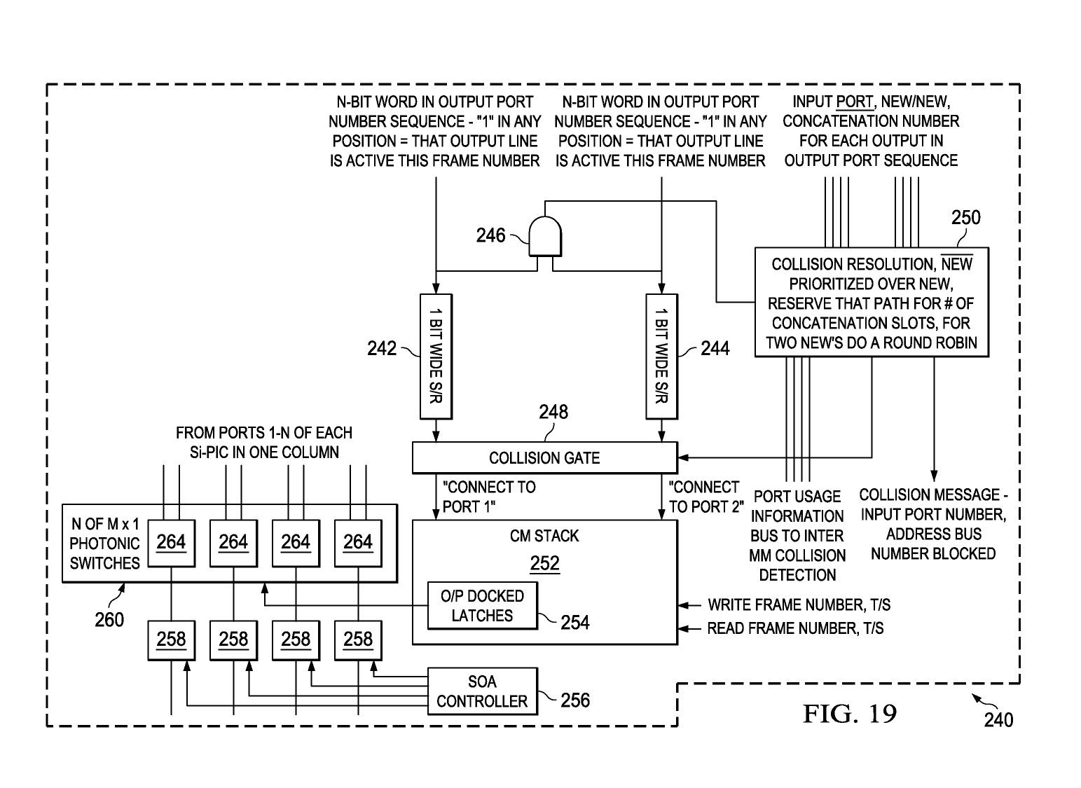

FIG. 16 illustrates contention detection and resolution system 270. An input contention resolution system, an output row contention resolution system (shown in detail in FIG. 19), and an output macromodule contention resolution system interact to form a fast switching fabric with built-in contention resolution.

In contention detection and resolution system 270, the signaling stream from the peripherals is received and converted from optical to electrical by optical to electrical (O/E) converters 292. Then, message frame aligners 290 align the message frames of the received connection requests. The connection requests across an input sub-group of N inputs from the N sources of the sub-group are converted into a notionally parallel multiplexed address bus in rectangular orthogonal multiplexers 288, which provide integrated intra-bus collision detection. Intra-bus contention detection block 286 performs the intra-bus contention detection by detecting requests for the same output destination address from different sources within the same frame, and passes contending time slots, whether the connection is new or not new priority, and the concatenation sequence numbers to intra-bus contention resolution block 278. In intra-bus detection module 282, rectangular orthogonal multiplexer 288 maps N serial input signaling streams from the N sources of the sub-group into an N time-slot parallel bus. The address destination portion of that bus has a width equal to log₂T (where T=P*M*N). Intra-bus contention detection block 286 compares parallel signaling address words across all of the timeslots of the signaling frame as they are created and identifies the output address contentions. Intra-bus contention resolution block 278 resolves the contention, for example using a round robin method, or prioritizing not new containers, which are containers other than the first container in a concatenated set of containers for carrying payloads larger than a single container. The output parallel multiplexed signaling bus is delayed by delay module 284, which may be a shift register, for example an extension of rectangular orthogonal multiplexer second plane shift registers to allow time for the contention resolution to be completed.

The address characteristics as a function of fabric port count and values of M, N, and P are included in block 280 within FIG. 16. The destination address length is given by log₂N+log₂M+log₂P bits. For N=32, M=2, and P=2, as illustrated in FIG. 16, the address is 7 bits for a 128×128 photonic switch. When N=32, M=4, and P=4, there are 9 address bits for a 512×512 photonic switch, and when N=64, M=4, and P=4, there are 10 address bits for a 1024×1024 photonic switch. Concatenation may add three bits, while cycling frame identifiers (IDs) add four bits for 16 frames or eight bits for 256 frames. Because of the time-slotted connection request bus, the originating source address does not need to be carried, because it may be obtained from the time slot position that the associated destination address occupies within the frame.

The input contention resolution block resolves which of the contending inputs is retained and which are rejected, producing a bus free of self-contention within the bus. The rejected connection requests are passed to collision detection resolution messaging block 272, which signals to the source peripherals to retransmit the contending containers. These signals are converted from electrical to optical signals by electrical-to-optical (E/O) converters 276 for transmission to the peripherals. ACK and NACK messages are transmitted to the source peripherals. The intra-signaling bus contention resolved signaling address bus is used to write connections to be set up in the appropriate PIC node's connection memory (CM) stack 386 using the macromodule select part of the input address to select a macromodule, the output column address part to select a column, and hence the PIC node on that macromodule. Then, the output port address is written into the appropriate selection PIC node's CM stack 220. A connection memory stack covering multiple frames may be used, because the connection requests are transmitted to the switch from the source peripherals well ahead of the completed payload-packed optical containers to be switched. A stacked store of frames of connections is used so the successful connection addresses (those which do not encounter output contention or survive the output contention processes) may be applied when the correct frame number timing is reached, and the associated optical payload container arrives to be switched. The size of this store (number of frames stored) depends on the signaling/traffic timing gap, which is the assembly and conditioning time of the container, for example between about 500 ns and about 5 μs. With a 40 ns frame and a 1 μs assembly time, a store of 25 frames may be used. In other switching applications where the assembly time is much shorter, the CM stack size may be substantially reduced.

The CM stack then immediately writes an in-sequence list of the output port addresses to be used in a particular frame to the column collision detectors 384, which identify when more than one PIC attempts to select the same output port in the same frame. The collision information is sent to contention resolution block 384, which gates the rejected connections and generates rejection information for collision detection resolution messaging block 272. Output block 168 and output block 162 each contains half of the N*M*P selectors 382, along with associated CM stack 386 and P port collision detection blocks 384. The NACKs and source addresses from both levels of collision detection are consolidated to override provisional ACKs. Contention is resolved between outputs of contending macromodules. Once the contention is resolved, the surviving addresses are written to the CM stack 220 associated with the appropriate output selectors 398.

Contention resolution is completed before the frame number when the actual switching takes place is reached. When the frame number is reached, the connections are set based on the CM maps, and all containers are photonically switched to their destinations. The container frame rate and speed may be such that the contention resolution takes more than one frame to complete. This is especially likely for short frames, and may be dealt with by sending connection requests early and delaying the actual traffic until the contention is resolved. Pipelining of some processes and stacking of connection maps in the CM stacks may be used.

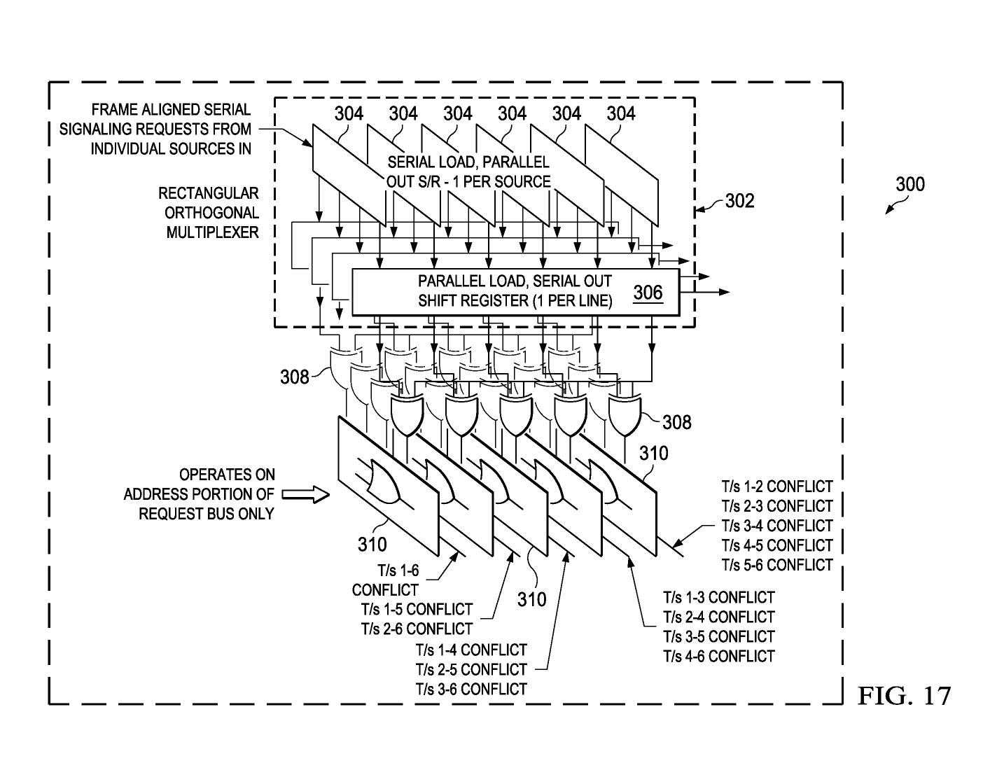

Because the input side contention detection and resolution system only deals with one bus, it is simple and fast acting. FIG. 17 illustrates rectangular orthogonal multiplexer module 300 with input side contention resolution. In the example illustrated in FIG. 17, the contention detection is performed during the rectangular orthogonal multiplexer serial-to-parallel conversion and read out process by feeding the address bits loaded into serial loaded, parallel input shift registers 304 with one shift register per line. The addresses are then loaded from input shift registers 304 into the parallel loaded, serial output shift registers 306 of the rectangular orthogonal multiplexer 302, as well as into an array of two input exclusive or (XOR) gates 308. The XOR gates provide an out value of 1 when the two inputs are the same and a 0 when the two inputs are different. These XOR gates are connected to the first shift register bit position, the first timeslot output, and the other bit positions along the shift register, for N−1 XOR gates per output line from the rectangular orthogonal multiplexer. The XOR array produces a series of 1 values when the comparison shows the same data in one bit of the requested output addresses between the first timeslot and every other timeslot. This structure is repeated for all of the output lines in the rectangular orthogonal multiplexer, so the array is producing all 1 values when they detect the same value of output address bits in a given timeslot comparison. For each timeslot, all of the outputs of the XOR gates are fed into AND gates 310, which produce a positive output only when all of the inputs are 1 values, which is when every XOR associated with that timeslot has the same output address value on both inputs. This occurs when that timeslot comparison has the same output address value on both inputs, when there is a collision.

Contention between the first timeslot and all the other timeslots is detected, not contention between the other timeslots, such as timeslot 2 and timeslot 4. However, for each timeslot, the rectangular orthogonal multiplexer output shifts the output by a timeslot, and a new output address moves into the head position, where it is compared to the remaining timeslots and outputs which have not yet been compared. Table 10 shows the inputs being compared in various timeslots.

TABLE 10

| | Time- | Time- | Time- | Time- | Time- | Time- |
|---|---|---|---|---|---|---|
| | slot 1 | slot 2 | slot 3 | slot 4 | slot 5 | slot 6 |
| Detection 1 | 1-2 | 2-3 | 3-4 | 4-5 | 5-6 | X |
| Detection 2 | 1-3 | 2-4 | 3-5 | 4-6 | X | |
| Detection 3 | 1-4 | 2-5 | 3-6 | X | | |
| Detection 3 | 1-5 | 2-6 | X | | | |
| Detection 4 | 1-6 | X | | | | |

Empty signaling requests or request slots may produce a spurious contention, because they may contain the same information. Contention reporting to the resolution block may be gated by the confirmation of a valid output address, not a blank or absent connection request. This may be resolved in a variety of ways. In one example, a two bit field is introduced into the non-address portion of the connection request. The two bits signal four states, where 00 indicates no request, 01 indicates a dummy container connection, 10 indicates a new request, and 11 indicates a continuing connection. This covers multiple scenarios and facilitates non-requests being removed. Dummy containers are used for background functions, such as far end receiver training in some systems, and have the lowest priority for containers. The highest priority containers are the continuing container requests, because they impact a train of containers which has already been partially sent.

The contention detection block creates a stream of identified contending addresses into the intra-bus contention resolution block, illustrated in FIG. 16. The identified contending address includes contending input addresses for two input timeslots, and hence the contending sources. The actual timeslot contents of the two contending timeslots may also be written into the contention resolution block, depending on whether the signaling of requests is frame content synchronous or spread over several frames, and whether container concatenation is used.

Intra-block contention resolution block 278 performs contention resolution on the input side. When the signaling of requests is frame content synchronous and the container content is not being concatenated, the contention resolution is a round robin prioritization. This approach is very fast, and may involve alternating early and late timeslots in the frame as having priority on alternate frames. In other examples, it rotates the number of the starting timeslot in a priority scheme, or the two approaches are combined.

In one example, when the signaling of requests is frame contention synchronous and the container content is concatenated, the continuation portions of the container concatenated flow may have priority over new containers to prevent amputating the back ends of concatenated container flows. This may performed in a variety of manners. For example, the signaling requests may contain a concatenation number and a new or not new bit to be sent with each signaling request. The new/not new bit is set to new for the initial request, and to not new for all further signaling requests for that concatenated container request, which would be repeated until the container sequence has been mapped into a complete set of frame timeslots. The contention resolution block may give priority to not new status over new status. When two new output addresses arrive for the same destination for the same frame, the contention resolution gives one of them priority, and the other one is rejected. When the one given priority is a concatenated container connection, the next time it is brought into contention with another demand from another port for the same output location and frame, it will be not new, and the other request is new. By giving requests that are not new priority over new requests, the ongoing allocation of capacity for the rest of the concatenated sequence is assured. This approach may be continued throughout the entire switch, including the output combining functions, but this involves the source signaling a separate request for each container of a concatenation container.

Another approach may be used with the inclusion of a container concatenation number. The container concatenation number stores the timeslot/output addresses for concatenation numbers greater than one. Then, in future frames, these stored addresses are used to preempt the timeslots and replace their contents with the stored address, with concatenation values decremented by one each frame until it reaches zero. Meanwhile, contention detection is performed with this stored address, which may be loaded into the appropriate stage of the second plane of shift registers in the rectangular orthogonal multiplexer in place of the downloading address. The downloading address is not needed, because the peripheral is sending a concatenated burst which it has already signaled. The existing contention detection system may be used.

Intra-bus contention resolution block 278 applies one of these approaches to create a list of connection requests to be blocked, which are gated out of the address bus flows to the macromodule and PICs, delaying the address bus, for example in a shift register, while the intra-bus contention block performs calculations. Connection requests which are removed are communicated to the collision detection resolution messaging block 272. This block has already read the connection bus and produced a set of provisional ACK messages to be communicated to the peripherals at the end of the contention resolution process. They are held, pending the arrival of the results of both the input side and output side contention resolution for the frame. Intra-bus contention resolution block 278 reports the connections it has removed to resolve contention to the collision detection resolution messaging block 272, which overwrites the contents of the appropriate provisional ACK messages with NACK messages, and transmits the NACK messages as it receives them. The ACK messages are held pending the arrival of the output side contention resolution. Once output side contention resolution is complete, an additional round of NACKs overwrite the appropriate provisional ACK messages, and both the NACK messages and the ACK messages, which are no longer provisional, are transmitted.

In the peripherals, a NACK triggers a retransmission process, and a new connection request follows. The container is sent from the sent container store when a NACK is received. When an ACK is received, the container copy is deleted from the sent container store, or it is marked for deletion, because an ACK indicates that the original sent container was successfully connected.

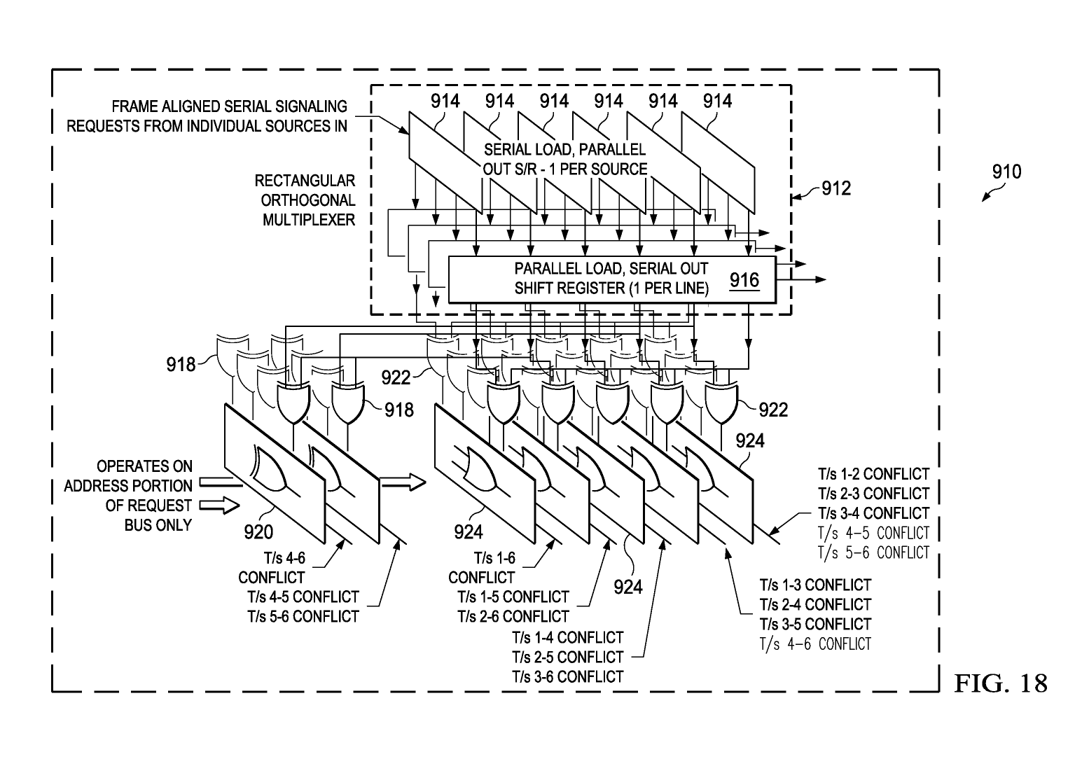

FIG. 18 shows input side contention detection block 910, which operates in a similar manner to that of FIG. 17, with rapid contention detection with fewer steps (time slots) of the outgoing shifting of the traffic in shift register 916. The contention detection is performed during the rectangular orthogonal multiplexer serial-to-parallel conversion and read out process by feeding the address bits loaded into the output shift registers 916 of the rectangular orthogonal multiplexer 912 from input shift registers 914, into an array of two XOR gates 922 and XOR gates 918. The XOR gates provide an out value of 1 when the two inputs are the same. These XOR gates are connected to the first shift register bit position, the first timeslot output, and the other bit positions along the shift register, for N−1 XOR gates per output line from the rectangular orthogonal multiplexer. The XOR array produces a series of 1 bit values when the comparison shows the same data in one bit of the requested output addresses between the first timeslot and every other timeslot. This structure is repeated for all of the output lines in the rectangular orthogonal multiplexer, so the array is producing all 1 values when they detect the same value of output address bits in a given timeslot comparison. For each timeslot, all of the outputs of the XOR gates 922 are fed into AND gates 924, and the outputs of the XOR gates 918 are fed into AND gates 920. The AND gates produce a positive output only when all of the inputs are 1 values, which is when every XOR associated with that timeslot has the same output address value on both inputs. This occurs when that timeslot comparison has the same output address value on both inputs, when there is a collision.

XOR gates 918 and AND gates 920 perform some of the timeslot comparisons earlier than the comparisons performed by XOR gates 308 and AND gates 310 in FIG. 17, (4-5, 5-5, and 5-6). Table 11 illustrates the inputs potential collisions are detected on during each timeslot. The overall collision detection is performed in half the number timeslots compared to the collision detection in Table 10, in 0.5N+1 timeslots. For a 32×32 switch, collision detection may be achieved in 17 timeslots with 15 additional detection arrays, for a total of 46 detection arrays.

TABLE 11

| | Timeslot 1 | Timeslot 2 | Timeslot 3 |
|---|---|---|---|
| Detection 1 | 1-2 | 2-3 | 3-4 |
| Detection 2 | 1-3 | 2-4 | 3-5 |
| Detection 3 | 1-4 | 2-5 | 3-6 |
| Detection 3 | 1-5 | 2-6 | 4-6 |
| Detection 4 | 1-6 | 4-5 | 5-6 |

Each of the input busses contains no more than one connection request per output port in any single frame, despite arising from N different independent sources. However, different input busses may contain connection requests for the same output port. The output side contention detection and resolution to address this is performed by output block contention detection and resolution system 240 in FIG. 19, which illustrates row output contention resolution. Macromodule output contention resolution may be similar, but without SOAs and an SOA controller. The output side contention detection and resolution provides inter-bus contention detection and resolution in two stages. The first stage is contention detection and resolution between the rows of the PICs outputting on the same column within a macromodule, and the second stage is contention detection and resolution of the multi-macromodule combination processes. The multi-macromodule combination process may also include providing the contention resolution back to the macromodule row and column contention. Alternatively, these may be separate processes.

In one example, the CM stacks of the PICs, such as CM stack 226 of FIG. 9, output information on which ports will be used in each upcoming frame, for example a word of the same number of bits as the number of output ports. For an N×N PIC, this may be N bits, which may be serial, parallel, or hybrid words containing a marking of the active outputs. For example, a 1 is marked for each active output port and a 0 is marked for inactive output ports. Alternatively, a 0 is used for active output ports and a 1 is used for inactive output ports.

The words from the PIC nodes, one per row, facing into a column, are fed through the output collision detector. The collision detector may contain AND gate 246 in a two port detection system. The collision detector seeks out points in the output words with 1 values in the same position. In a collision detection system with more than two ports, a collision is detected when there is more than one user of a port. A collision is detected when more than one PIC in a column attempts to output into a given output port in a given frame period. The output numbers, corresponding to output ports where a collision occurs, are passed on to contention resolution block 250, which applies a priority scheme. For example, a round robin priority scheme may be used, causing one of the contending requests to be passed to the output selector CM stack 252, so the output of the selector switch from the macromodule selects that output from the selected PIC, and the other outputs, and their input time slot values, are reported to collision detection resolution messaging block 272 of FIG. 16 via output block 168 of FIGS. 9A-D, which adds additional communications. Alternatively, the macromodule output contention resolution block examines additional aspects of the address bus information, such as the “new”/“not new” bits to ensure continuing connectivity being prioritized to subsequent parts of the transmission of a block of concatenated containers.

The requests from the PIC CM stacks are represented by lists of intended outputs per frame, and are passed to collision gate 248 through one bit wide shift registers 242, 244. Duplicate requests are reduced to one surviving address request from contention resolution block 250. The other request(s) are rejected and a NACK message is sent to trigger a retransmission. Then, the modified output lists are used to write the macromodule output selector switch from CM stack 252. CM stack 252 contains output clocked latches 254. The output clocked latches 254 are used to control switches 264 of selector switch 260, M×1 photonic switches used to select the approved outputs. The outputs are amplified by SOAs 258, which are controlled by SOA controllers 256.

This process may be repeated through the output block 168 in FIGS. 9A-D, which combines or merges the outputs from the switching macromodules similarly to the macromodule output selected merged outputs in the PICs. The words from macromodules, one per row, facing into a column, are fed through a collision detector. The collision detector may contain an AND gate in a two port detection system. The collision detector seeks points in the output words with 1 values in the same position. In a collision detection system with more than two ports, a collision is detected when there is more than one use of a port. A collision is detected when more than one macromodule in a column attempts to output into a given output port in a given frame period. The output numbers, corresponding to output ports where a collision occurs, are passed on to a contention resolution block, which applies a priority scheme. For example, a round robin priority scheme may be used, causing one of the contending requests to be passed to the output row selector 398, so the output of the selector switch from the macromodule selects that output from the selected macromodule, and the other outputs, and their input time slot values, are reported to collision detection resolution messaging block 272 of FIG. 16.

When the multi-macromodule collision detection process is complete, messages indicating the connections from both the PIC row selection and the macromodule selection steps are rejected, and collision detection resolution messaging block 272 overwrites the contents of the appropriate provisional ACK messages with a NACK, and transmits those messages to the source peripheral to trigger a re-send. Then, the remaining, now confirmed, ACK messages are transmitted to the peripherals. These peripherals may then delete the relevant container from the sent container store.

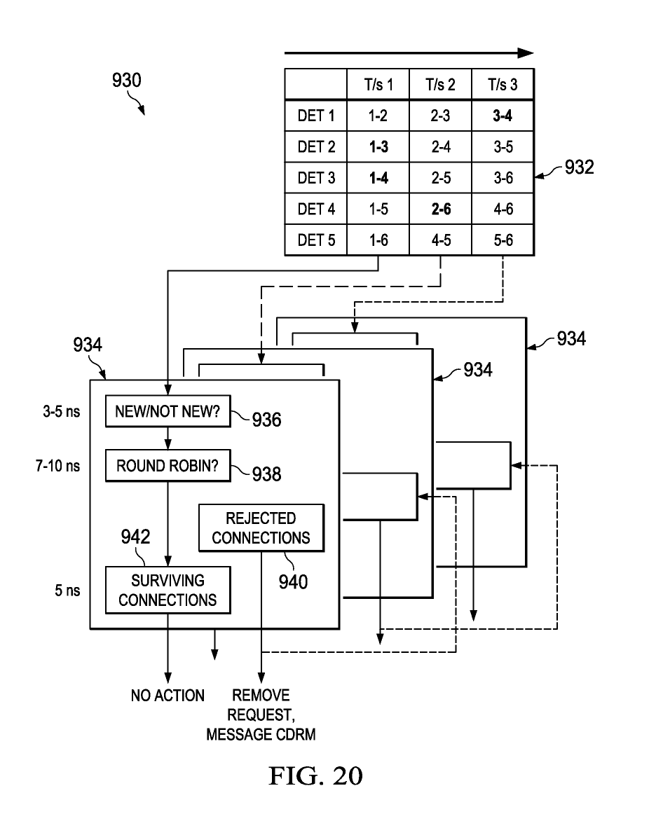

FIG. 20 illustrates flowchart 930 for a method of performing contention resolution. Input side contention resolution is performed within each input bus, as illustrated in FIG. 16. The locations in contention resolution grid 932 are run though the contention resolution process. The contention pairs are examined by blocks 934, with one block per input bus occurring in parallel. Initially, each contention pair of connections is examined to determine whether they are “new” or “not new” in block 936. When one of the connections is “not new”, and the other connection is “new”, the “not new” connection is given priority, because it is the second or later frame of a concatenated connection. When both connections are “new”, the system proceeds to step 938. Both connections will not be “not new”, because only one of them would have had priority for the previous frame.

In step 938, round robin allocation is performed. A fast fairness algorithm, such as rotating the starting point for a next one up the source number chain gets priority, or a higher/lower source address gets priority, may be used.

The surviving connections, in step 942, do not require action in the contention resolution block. They are propagated into the switch.

Step 940 handles the rejected connections. A rejected connection request is prevented from propagating into the switch fabric connection memories, for example by blanking the connection as it exits the address delay shift register. When the delay through the contention resolution is multiple frames and concatenation is used, an intermediate location in the address delay shift register may be blanked, one frame removed from the gated out exiting address. Also, the source is notified so it may retransmit the rejected container in a later frame. This is performed by the collision detection resolution messaging block, which messages the NACK back to the source peripherals.

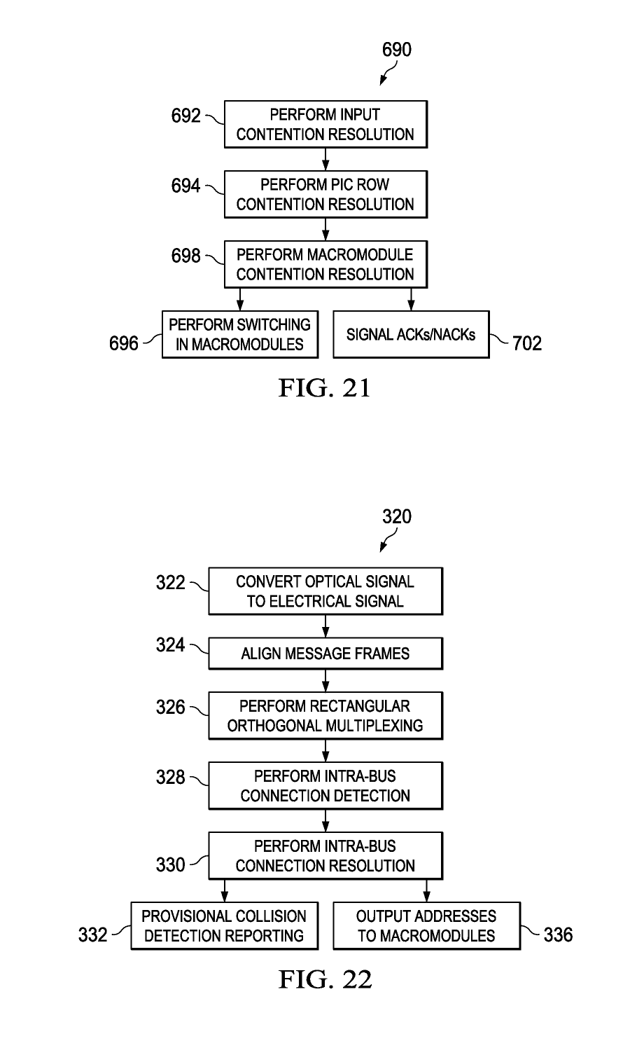

FIG. 21 illustrates flowchart 690 for a method of contention resolution in an ultrafast photonic switch. Initially, in step 692, input contention resolution is performed. Collisions within each signaling request bus are detected and resolved. When a collision is detected on the input bus, one of the input requests is selected for switching, and directed to the macromodule switching module. Other container(s) are not selected, and are not sent to the macromodule switching module. For the not selected inputs, NACKs are sent to the source peripherals. For selected containers, provisional ACKs are saved.

Next, in step 694, contention resolution is performed between specific PICs on each of the rows of PICs which are interfacing into each specific column. Collisions are detected on output ports of specific PICS within rows of PICs interfacing into each specific column for an upcoming frame. One output is selected, and other output(s) are rejected. The approved connections are saved in the CM stack, which are later used by the selector switch to accept the appropriate output. NACKs are sent for rejected containers.

Then, in step 698, macromodule contention resolution is performed. Collisions are detected between outputs of macromodules based on the containers which are provisionally selected based on the rows of PICs. One output is selected for a port, and other output(s) are rejected. NACKs are sent for rejected containers, and ACKs are sent for selected containers. The results are saved on the CM stack, and outputs for the output container are selected by a selection switch.

In step 696, optical switching is performed in the PICs in the macromodules. Input optical streams are split, with a portion of the optical power directed towards all macromodules on one row or column of the photonic switching structure. The input optical streams are received by the macromodule. They are polarization split and rotated, to produce two optical streams having the same polarization. These optical streams are further split by power splitters to be directed towards PIC nodes in a row of a macromodule. Addresses have already been stored in the CM stacks of the PIC nodes. The connections on the PICs are set up by a PIC controller based on the CM stack for the current frame. PICs and columns are selected. The containers are optically switched. Outputs are selected based on the PIC row contention resolution. The selected outputs are polarization rotated and combined, and transmitted from the macromodules. They are then selected by a macromodule selector based on the macromodule contention resolution.

In step 702, final NACKs and ACKs are transmitted. NACKs are transmitted as they are determined by the contention resolution, based on input contention resolution, PIC row contention resolution, and macromodule contention resolution. ACKs are only transmitted after contention resolution is complete.

FIG. 22 illustrates flowchart 320 for a method of input stage contention resolution. Initially, in step 322, the input optical signals are received from the peripherals. The received optical signals are converted from optical signals to electrical signals.

Next, in step 324, message frames of the input electrical signals are aligned.

In step 326, rectangular orthogonal multiplexing is performed. The connection requests are converted into notionally parallel multiplexed address buses. Intra-bus collision detection is integrated into the rectangular orthogonal multiplexers. The aligned serial signaling requests from the shift registers are loaded onto parallel load, serial output shift registers. Addresses are compared to each other. It is determined which addresses are the same for the same frame. The addresses are delayed, for example by shift registers, to wait for the input contention resolution.

Then, in step 328 intra-bus contentions are detected. For example, contention is detected when more than one container in a bus uses the same output port.

In step 330, contention resolution is performed when contention is detected in step 328. In one example, round robin contention resolution is performed. Alternatively, when contention is used, not new containers have priority over new containers. Then, when colliding containers are all new, round robin contention resolution may be performed.

In step 332, intra-bus collision detection reporting is performed. When a container is not selected, NACKs are immediately sent to the peripheral(s) for re-transmission. When a container is selected, a provisional ACK is stored. However, ACKs are not transmitted to the source peripherals until collision detection and resolution is complete.

Meanwhile, in step 336, the addresses of the containers selected in step 330 are output to the macromodules. These addresses are to be stored in the CM stacks.

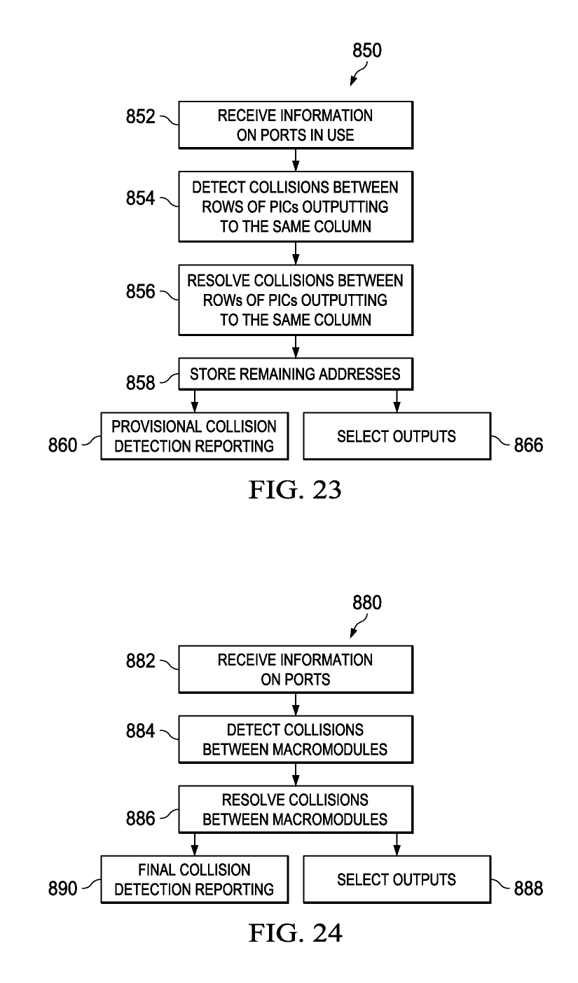

FIG. 23 illustrates flowchart 850 for an embodiment method of performing output contention resolution on PIC rows. This method may be performed on a macromodule. Initially, in step 852, information on ports requested to be used is received. This is stored on a CM stack.

Next, in step 854, collisions are detected between output ports in the same row within a macromodule. A collision is detected when two containers have the same output port for the same frame.

Then, in step 856, collisions are resolved. In one example, round robin contention resolution is performed. Alternatively, when concatenation is used, not new containers have priority over new containers. Then, when colliding containers are all new, round robin contention resolution may be performed.

In step 858, the addresses of the surviving containers are stored in the CM stack. This will be used to select row outputs by a selector switch.

In step 860, provisional collision detection reporting is performed. When containers are not selected, NACKs are immediately sent to the peripherals for retransmission. When a container is selected, a provisional ACK continues to be stored. ACKs are not transmitted to the peripherals until collision detection and resolution is complete.

Finally, in step 866, the outputs are selected using a selector switch based in the information stored in the CM stack. Only the outputs which have survived output contention resolution are selected. Outputs for other optical streams are switched through the PICs, but are not selected, and are therefore not output.

FIG. 24 illustrates flowchart 880 for an embodiment method of performing output contention resolution between macromodules. This contention resolution may be performed in a dedicated module. Initially, in step 882, information on output ports being used is received from the macromodules.

Next, in step 884, collisions are detected in the outputs between the macromodule. When more than one macromodule attempts to use the same output on the same frame, a collision is detected.

Then, in step 886, collisions are resolved. In one example, round robin contention resolution is performed. Alternatively, when concatenation is used, not new containers have priority over new containers. Then, when colliding containers are all new, round robin contention resolution may be performed.

In step 890, final collision detection reporting is performed. NACKs are transmitted to the peripherals. Also, surviving ACKs, which are now final, are transmitted to the peripherals.

Additionally, in step 888, the outputs are selected based on the collision resolution. This may be done using a selection switch based on the information stored in the CM stack. Not selected outputs are still switched by the PICs, but the outputs are not selected.

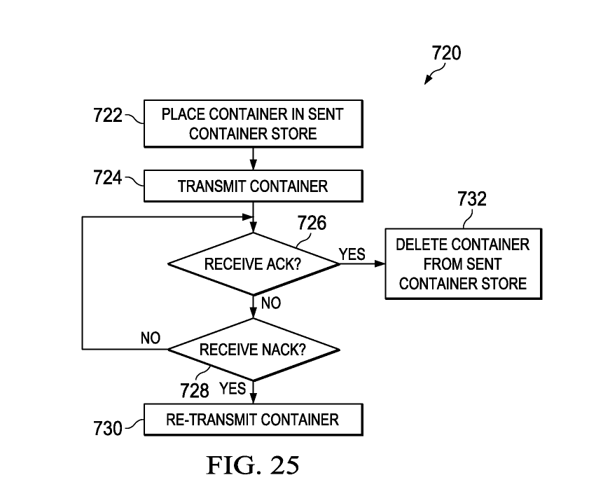

FIG. 25 illustrates flowchart 720 for an embodiment method of contention resolution performed by the peripherals. Initially, in step 722, a container is selected for transmission. This container is stored in a sent container store.

Then, in step 724, the container is transmitted to a photonic switch for switching. The connection request is sent in advance of the container. However, the container is transmitted before receiving an ACK from the photonic switch.

In step 726, the peripheral determines whether it has received an ACK from the photonic switch. When the peripheral receives an ACK, it proceeds to step 732 to delete the container from the sent container store or mark it for deletion. When the peripheral does not receive an ACK, it proceeds to step 728.

In step 728, the peripheral determines whether it has received a NACK. When the peripheral has not received a NACK, it proceeds to step 726 to continue waiting to receive an ACK or a NACK. When the peripheral receives a NACK, it proceeds to step 730 to retransmit the container and the connection request.

An embodiment photonic switching structure includes a first macromodule, where the first macromodule includes an array of switch matrix photonic integrated circuit (PIC) nodes having a first row, a second row, a first column, and a second column and a first optical splitter optically coupled to PIC nodes in the first row. The first macromodule also includes a second optical splitter optically coupled to PIC nodes in the second row and a first output selector optically coupled to PIC nodes in the first column. Additionally, the first macromodule includes a second output selector optically coupled to PIC nodes in the second column and a first collision detector coupled to PIC nodes in the first column. Also, the first macromodule includes a second collision detector coupled to PIC nodes in the second column.

In an embodiment, a PIC node of the array of switch matrix PIC nodes includes a PIC and a PIC controller electrically coupled to the PIC. In an embodiment, the PIC node of the array of switch matrix PIC nodes further includes a connection memory (CM) stack. In another embodiment, an optical macromodule substrate of the PIC node has a well or aperture, where the PIC controller is in the well, and where an active surface of the PIC is mounted on an active surface of the PIC controller. For example, the PIC controller is electrically coupled to the macromodule substrate the PIC.

In an additional embodiment, the first macromodule further includes a first CM stack electrically coupled to the first output selector and the first collision detector and a second CM stack electrically coupled to the second output selector and the second collision detector.

In a further embodiment, the photonic switching structure includes an array of macromodules including the first macromodule, where the array of macromodules has a first row of macromodules, a second row of macromodules, a first column of macromodules, and a second column of macromodules. An embodiment further includes a first output selection module optically coupled to macromodules of the first row of macromodules and a second output selection module optically coupled to macromodules of the second row of macromodules. For example, the first output selection module includes a macromodule collision detector, a CM stack electrically coupled to the macromodule collision detector, and a third output selector electrically coupled to the CM stack. In another embodiment, a macromodule of the array of macromodule includes an array of PICs. For example, the array of PICs includes a first pair of rows of PICs including a first row and a second row, where the first row is optically coupled to a polarization rotator splitter, and where the second row is optically coupled to the polarization rotator splitter.

In another embodiment, the first macromodule further includes a PIC selector configured to select a PIC node of the array of switch matrix PIC nodes in accordance with a PIC selection address to produce a selected PIC and a column selector configured to select a column of the selected PIC in accordance with a column address.

In an additional embodiment, the first macromodule further includes a plurality of semiconductor optical amplifiers (SOAs) optically coupled to the array of switch matrix PIC nodes.

An embodiment method includes serially loading signaling input port requests into a plurality of input shift registers and loading addresses from the plurality of input shift registers into a plurality of output shift registers. The method also includes reading out comparison bits from the plurality of output shift registers and determining input port contention in accordance with the comparison bits.

In an embodiment, determining input port contention further includes comparing address bits with a plurality of exclusive OR (XOR) gates to produce comparison addresses and gating the comparison addresses with a plurality of AND gates to produce a conflict list. In an embodiment, a number of XOR gates is greater than or equal to a number of input ports minus one.

Another embodiment further includes receiving an optical signal, converting the optical signal to an electrical signal and aligning message frames of the electrical signal to produce the signaling input port requests.

A further embodiment includes resolving input port contention when detecting input port contention. In an embodiment, resolving the input port contention includes round robin input port contention resolution. In another embodiment, resolving the input port contention includes prioritizing continuing containers over new containers.

An embodiment method includes receiving a plurality of output port requests for a frame and detecting collisions between the plurality of output port requests. The method also includes resolving detected collisions by selecting a first output port request for a first requested output port, and rejecting remaining output port requests and selecting a first output of a photonic switch module in accordance with the first output port request to connect the first output of the photonic switch module to the first requested output port. Additionally, the method includes transmitting negative acknowledgments (NACKs) corresponding to the rejected output port requests.

An embodiment also includes transmitting an acknowledgment (ACK) in accordance with the first output port request.

In another embodiment, detecting collisions includes detecting collisions within a macromodule.

In an additional embodiment, detecting collisions includes detecting collisions between macromodules.

A further embodiment includes receiving, a fixed period of time after receiving the first output port request, a first optical container corresponding to the first requested output port.

Another embodiment includes converting the plurality of output port requests from serial to a parallel before detecting the collisions.

An embodiment method includes transmitting, by a peripheral to a photonic switch, a connection request corresponding to a container to be assembled and transmitting, by the peripheral to a photonic switch, the container. The method also includes storing a copy of the container in a sent container store and determining whether a negative acknowledgment (NACK) corresponding to the connection request has been received. Additionally, the method includes re-transmitting, by the peripheral to the photonic switch, the copy of the container in response to receiving the NACK.

An embodiment includes determining whether an acknowledgment (ACK) corresponding to the connection request has been received and deleting the copy of the container stored in the sent container store when an ACK has been received.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A photonic switching structure comprising a first macromodule, wherein the first macromodule comprises:
an array of switch matrix photonic integrated circuit (PIC) nodes having a first row, a second row, a first column, and a second column;
a first optical splitter optically coupled to PIC nodes in the first row;
a second optical splitter optically coupled to PIC nodes in the second row;
a first output selector optically coupled to PIC nodes in the first column;
a second output selector optically coupled to PIC nodes in the second column;
a first collision detector coupled to PIC nodes in the first column; and
a second collision detector coupled to PIC nodes in the second column.

2. The photonic switching structure of claim 1, wherein a PIC node of the array of switch matrix PIC nodes comprises:
a PIC; and
a PIC controller electrically coupled to the PIC.

3. The photonic switching structure of claim 2, wherein the PIC node of the array of switch matrix PIC nodes further comprises a connection memory (CM) stack.

4. The photonic switching structure of claim 2, wherein an optical macromodule substrate of the PIC node has a well or aperture, wherein the PIC controller is in the well, and wherein an active surface of the PIC is mounted on an active surface of the PIC controller.

5. The photonic switching structure of claim 4, wherein the PIC controller is electrically coupled to the macromodule substrate the PIC.

6. The photonic switching structure of claim 1, wherein the first macromodule further comprises:
a first CM stack electrically coupled to the first output selector and the first collision detector; and
a second CM stack electrically coupled to the second output selector and the second collision detector.

7. The photonic switching structure of claim 1, wherein the photonic switching structure comprises an array of macromodules comprising the first macromodule, wherein the array of macromodules has a first row of macromodules, a second row of macromodules, a first column of macromodules, and a second column of macromodules.

8. The photonic switching structure of claim 7, further comprising:
a first output selection module optically coupled to macromodules of the first row of macromodules; and
a second output selection module optically coupled to macromodules of the second row of macromodules.

9. The photonic switching structure of claim 8, wherein the first output selection module comprises:
a macromodule collision detector;
a CM stack electrically coupled to the macromodule collision detector; and
a third output selector electrically coupled to the CM stack.

10. The photonic switching structure of claim 7, wherein a macromodule of the array of macromodule comprises an array of PICs.

11. The photonic switching structure of claim 10, wherein the array of PICs comprises a first pair of rows of PICs comprising a first row and a second row, wherein the first row is optically coupled to a polarization rotator splitter, and wherein the second row is optically coupled to the polarization rotator splitter.

12. The photonic switching structure of claim 1, wherein the first macromodule further comprises:
a PIC selector configured to select a PIC node of the array of switch matrix PIC nodes in accordance with a PIC selection address to produce a selected PIC; and
a column selector configured to select a column of the selected PIC in accordance with a column address.

13. The photonic switching structure of claim 1, wherein the first macromodule further comprises a plurality of semiconductor optical amplifiers (SOAs) optically coupled to the array of switch matrix PIC nodes.

14. A method comprising:
serially loading signaling input port requests into a plurality of input shift registers;
loading addresses from the plurality of input shift registers into a plurality of output shift registers;
reading out comparison bits from the plurality of output shift registers; and
determining input port contention in accordance with the comparison bits.

15. The method of claim 14, wherein determining input port contention further comprises:
comparing address bits with a plurality of exclusive OR (XOR) gates to produce comparison addresses; and
gating the comparison addresses with a plurality of AND gates to produce a conflict list.

16. The method of claim 15, wherein a number of XOR gates is greater than or equal to a number of input ports minus one.

17. The method of claim 14, further comprising:
receiving an optical signal;
converting the optical signal to an electrical signal; and
aligning message frames of the electrical signal to produce the signaling input port requests.

18. The method of claim 14, further comprising resolving the input port contention using round robin input port contention resolution.

19. The method of claim 14, further comprising resolving the input port contention by prioritizing continuing containers over new containers.

20. A method comprising:
receiving a plurality of output port requests for a frame;
detecting collisions between the plurality of output port requests;
resolving detected collisions by selecting a first output port request for a first requested output port, and rejecting remaining output port requests;
selecting a first output of a photonic switch module in accordance with the first output port request to connect the first output of the photonic switch module to the first requested output port; and
transmitting negative acknowledgments (NACKs) corresponding to the rejected output port requests.

21. The method of claim 20, further comprising transmitting an acknowledgment (ACK) in accordance with the first output port request.

22. The method of claim 20, wherein detecting collisions comprises detecting collisions within a macromodule.

23. The method of claim 20, wherein detecting collisions comprises detecting collisions between macromodules.

24. The method of claim 20, further comprising receiving, a fixed period of time after receiving the first output port request, a first optical container corresponding to the first requested output port.

25. The method of claim 20, further comprising converting the plurality of output port requests from serial to a parallel before detecting the collisions.

26. A method comprising:
transmitting, by a peripheral to a photonic switch, a connection request corresponding to a container to be assembled;
transmitting, by the peripheral to a photonic switch, the container;
storing a copy of the container in a sent container store;
determining whether a negative acknowledgment (NACK) corresponding to the connection request has been received; and
re-transmitting, by the peripheral to the photonic switch, the copy of the container in response to receiving the NACK.

27. The method of claim 26, further comprising
determining whether an acknowledgment (ACK) corresponding to the connection request has been received; and
deleting the copy of the container stored in the sent container store when an ACK has been received.
